(19) United States
(12) Patent Application Publication
(10) Pub. No.: US 2024/0145387 A1
(43) Pub. Date: May 2, 2024

(54) SEMICONDUCTOR DEVICE INCLUDING A CONTACT PLUG

(71) Applicant: SAMSUNG ELECTRONICS CO., LTD., SUWON-SI (KR)

(72) Inventors: Jaemoon Lee, SUWON-SI (KR); Jeongik Kim, SUWON-SI (KR); Sungyu Choi, SUWON-SI (KR); Rakhwan Kim, SUWON-SI (KR); Chunghwan Shin, SUWON-SI (KR)

(21) Appl. No.: 18/329,784

(22) Filed: Jun. 6, 2023

(30) Foreign Application Priority Data
Oct. 26, 2022 (KR) 10/2022/0139623

(51) Int. Cl. H01L 23/528; H01L 23/522; H01L 29/06; H01L 29/423; H01L 29/775; H01L 29/786

(52) U.S. Cl. CPC H01L 23/5283; H01L 23/5226; H01L 29/0673; H01L 29/42392; H01L 29/775; H01L 29/78696; H01L 29/66545

(57) ABSTRACT

A semiconductor device includes a gate structure disposed on a substrate and a contact plug. The contact plug includes a first conductive pattern contacting an upper surface of the first gate structure and a second conductive pattern contacting an upper surface of the first conductive pattern. An upper surface of a central portion of the first conductive pattern is higher than an upper surface of an edge portion of the first conductive pattern. A lower surface of a central portion of the second conductive pattern is higher than a lower surface of an edge portion of the second conductive pattern.

### CROSS-REFERENCE TO RELATED APPLICATION

This application claims priority under 35 USC § 119 to Korean Patent Application No. 10-2022-0139623, filed on Oct. 26, 2022 in the Korean Intellectual Property Office (KIPO), the contents of which are herein incorporated by reference in their entirety.

### TECHNICAL FIELD

The present disclosure relates to a semiconductor device and, more particularly, to a semiconductor device having a contact plug.

### DISCUSSION OF THE RELATED ART

In a logic device, a contact plug structure may be formed to connect a gate structure to upper wirings. As the aspect ratio of the contact plug increases and the diameter thereof decreases, voids or seams may occur inside the contact plug during the process of forming the contact plug, thereby deteriorating electrical characteristics of the contact plug.

### SUMMARY

A semiconductor device includes a gate structure disposed on a substrate and a contact plug. The contact plug includes a first conductive pattern contacting an upper surface of the first gate structure and a second conductive pattern contacting an upper surface of the first conductive pattern. An upper surface of a central portion of the first conductive pattern is higher than an upper surface of an edge portion of the first conductive pattern. A lower surface of a central portion of the second conductive pattern is higher than a lower surface of an edge portion of the second conductive pattern.

A semiconductor device includes a gate structure disposed on a substrate and a contact plug. The contact plug includes a first conductive pattern contacting an upper surface of the first gate structure and a second conductive contacting an upper surface of the first conductive pattern. An upper surface of an edge portion of the first conductive pattern is higher than an upper surface of a central portion of the first conductive pattern. A lower surface of a central portion of the second conductive pattern is lower than a lower surface of an edge portion of the second conductive pattern. A width of the edge portion of the first conductive pattern, in a horizontal direction substantially parallel to an upper surface of the substrate, is smaller than a thickness of the substrate of the central portion of the first conductive pattern, in a vertical direction substantially perpendicular to the upper surface.

A semiconductor device includes an active pattern disposed on a substrate. The active pattern extends in a first direction substantially parallel to an upper surface of the substrate. A gate structure is disposed on the active pattern. The gate structure extends in a second direction that is substantially parallel to the upper surface of the substrate and crosses the first direction. A source/drain layer is disposed on the active pattern adjacent to the gate structure in the first direction. A plurality of channels are spaced apart from each other in a third direction that is substantially perpendicular to the upper surface of the substrate. An insulating interlayer is disposed on the gate structure. A contact plug extends through the insulating interlayer and contacts an upper surface of the gate structure. The contact plug includes a first conductive pattern including a first metal and a second conductive pattern contacting an upper surface of the first conductive pattern and including a second metal. An upper surface of a central portion of the first conductive pattern is higher than an upper surface of an edge portion of the first conductive pattern. A lower surface of a central portion of the second conductive pattern is higher than a lower surface of an edge portion of the second conductive pattern.

### BRIEF DESCRIPTION OF THE DRAWINGS

FIG. 1 is a plan view illustrating a semiconductor device in accordance with example embodiments.

FIGS. 2 to 4 are cross-sectional views illustrating a semiconductor device in accordance with example embodiments.

FIGS. 5, 8, 12, 15, and 17 are plan views illustrating a method of manufacturing a semiconductor device in accordance with example embodiments.

FIGS. 6, 7, 9-11, 13, 14, 16, and 18 to 23 are cross-sectional view illustrating a method of manufacturing a semiconductor device in accordance with example embodiments.

FIG. 24 is a cross-sectional view illustrating a semiconductor device in accordance with example embodiments, corresponding to FIG. 3.

FIG. 25 is a cross-sectional view illustrating a semiconductor device in accordance with example embodiments, corresponding to FIG. 3.

FIG. 26 is a cross-sectional view illustrating a semiconductor device in accordance with example embodiments, corresponding to FIG. 3.

FIG. 27 is a plan view illustrating a semiconductor device in accordance with example embodiments.

FIGS. 28 to 30 are cross-sectional views illustrating a semiconductor device in accordance with example embodiments.

FIGS. 31, 33, 36, and 40 are plan views illustrating a method of manufacturing a semiconductor device in accordance with example embodiments.

FIGS. 32, 34, 35, 37-39, 41, and 42 are cross-sectional views illustrating a method of manufacturing a semiconductor device in accordance with example embodiments.

FIGS. 43 to 45 are cross-sectional views illustrating semiconductor devices in accordance with example embodiments.

### DESCRIPTION OF EMBODIMENTS

A semiconductor device and a method of manufacturing the same in accordance with example embodiments will be described more fully hereinafter with reference to the accompanying drawings. Hereinafter in the specifications, two directions substantially parallel to an upper surface of a substrate and crossing each other may be referred to as first and second directions D1 and D2, respectively, and a direction substantially perpendicular to the upper surface of the substrate may be referred to as a third direction D3. In example embodiments, the first and second directions D1 and D2 may be substantially perpendicular to each other.

In the semiconductor device in accordance with example embodiments, a contact plug contacting an upper surface of a gate structure might be made free of voids and seams inside thereof. Thus, the contact plug may have enhanced electrical characteristics such as reduced electrical resistance.

In addition, during a process of forming the contact plug including first and second conductive patterns being sequentially stacked, the first conductive pattern may be formed to have a sufficient thickness on the gate structure, and thus fluorine (F) and/or chlorine (Cl) included in a source gas used when forming the second conductive pattern may be prevented from penetrating into the gate structure and deteriorating the electrical characteristics of the gate structure.

The contact plug might not include a barrier pattern covering sidewalls and lower surfaces of the first and second conductive patterns, and thus the contact plug may have low electrical resistance.

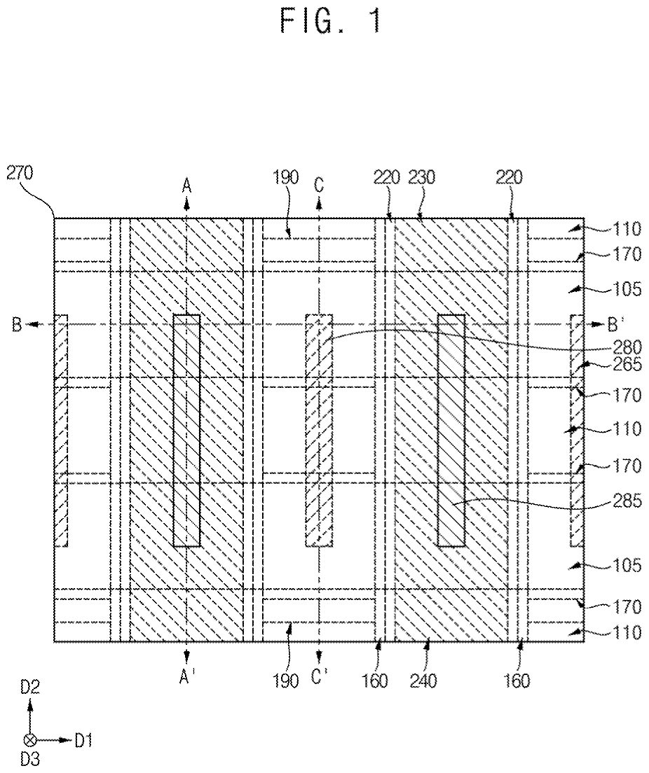

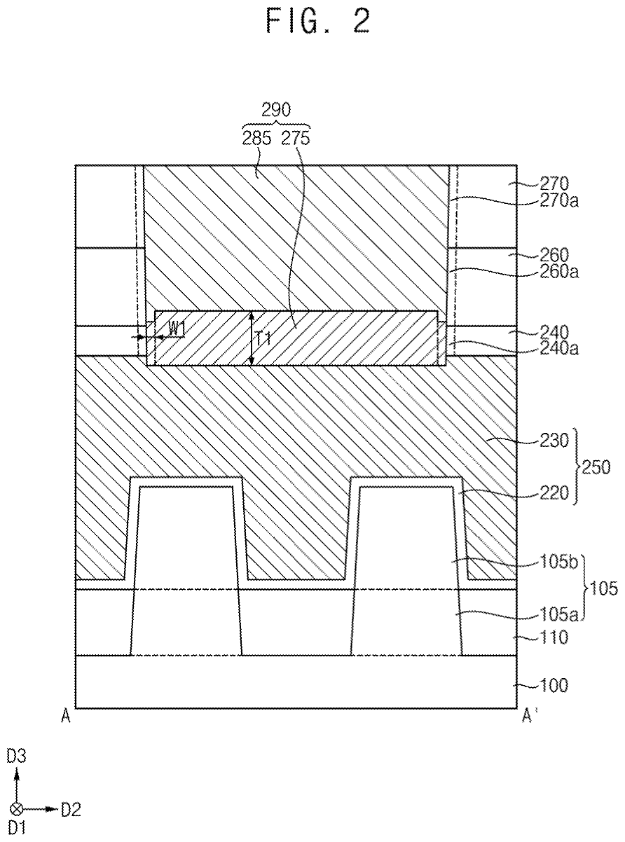

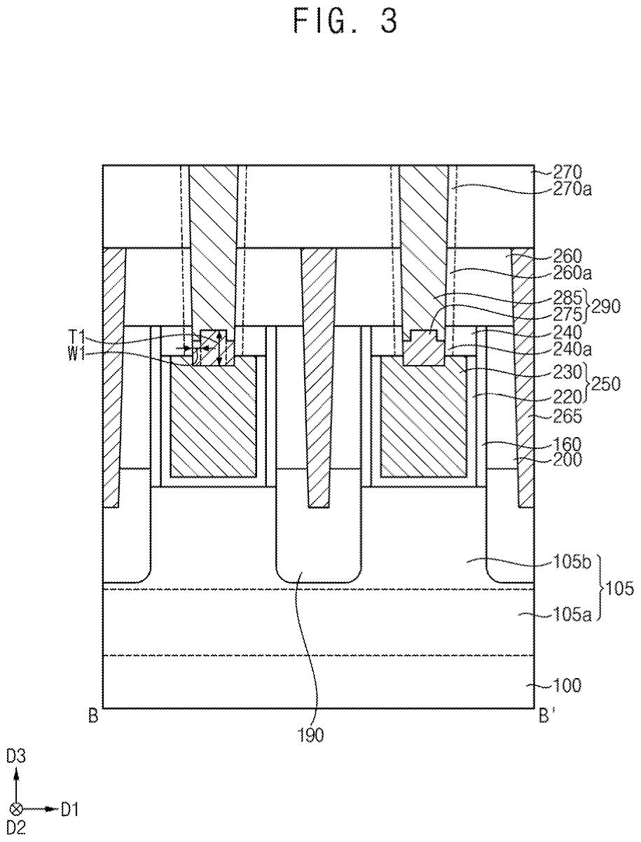

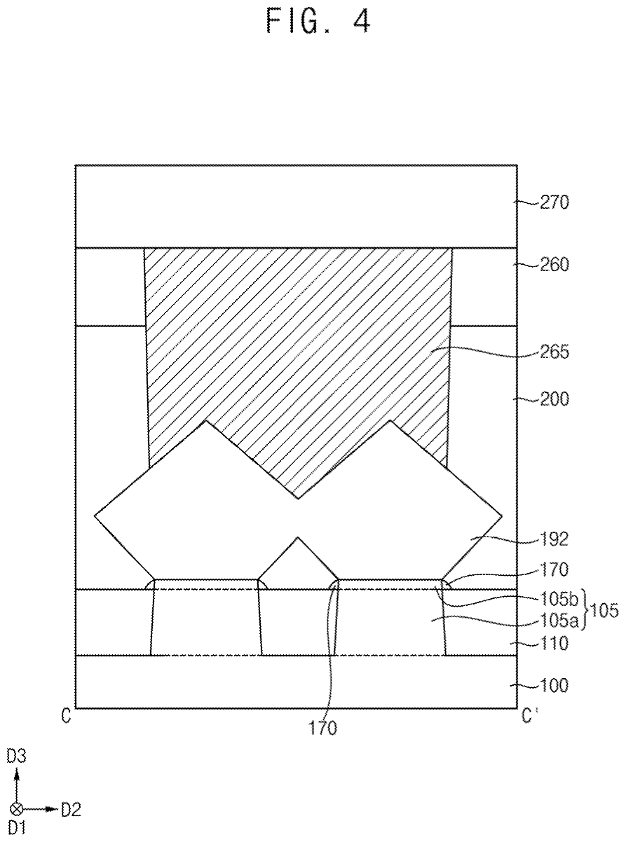

FIGS. 1 to 4 are a plan view and cross-sectional views illustrating a semiconductor device in accordance with example embodiments. For example, FIG. 1 is the plan view, and FIGS. 2 to 4 are the cross-sectional views. FIG. 2 is a cross-sectional view taken along line A-A′ of FIG. 1, FIG. 3 is a cross-sectional view taken along line B-B′ of FIG. 1, and FIG. 4 is a cross-sectional view taken along line C-C′ of FIG. 1.

Referring to FIGS. 1 to 4, the semiconductor device may include a first gate structure 250 and a second contact plug 290.

Also, the semiconductor device may include a first active pattern 105, a first gate spacer 160, a fin spacer 170, a first source/drain layer 190, a first capping pattern 240, a first contact plug 265 and first to third insulating interlayers 200, 260 and 270.

The substrate 100 may include a semiconductor material, e.g., silicon, germanium, silicon-germanium, etc., or III-V semiconductor compounds, e.g., GaP, GaAs, GaSb, etc. In some embodiments, the substrate 100 may include a silicon-on-insulator (SOI) substrate or a germanium-on-insulator (GOI) substrate.

The first active pattern 105 may have a fin-like shape protruding from an upper surface of the substrate 100, and thus may also be referred to as a first active fin. A lower sidewall of the first active pattern 105 may be covered by the first isolation pattern 110. The substrate 100 may include a field region on which the first isolation pattern 110 is formed and an active region on which the first active pattern 105 is formed.

The first active pattern 105 may include a first lower active pattern 105a of which a sidewall is covered by the first isolation pattern 110 and a first upper active pattern 105b of which a sidewall is not covered by the first isolation pattern 110. In example embodiments, the first active pattern 105 may extend in the first direction D1, and a plurality of first active patterns 105 may be spaced apart from each other in the second direction D2.

The first active pattern 105 may include a material that is substantially the same as that of the substrate 100, and the first isolation pattern 110 may include an oxide, e.g., silicon oxide.

In example embodiments, the first gate structure 250 may extend in the second direction D2 on the first active pattern 105 and the first isolation pattern 110 on the substrate 100, and a plurality of first gate structures 250 may be spaced apart from each other in the first direction D1.

In example embodiments, the first gate structure 250 may include a first gate insulation pattern 220 and a first gate electrode 230 stacked on the first active pattern 105 and the first isolation pattern 110. The first gate insulation pattern 220 may cover a lower surface and a sidewall of the first gate electrode 230.

In an example embodiment, the first gate structure 250 may further include a first interface pattern disposed between the first gate insulation pattern 220 and the first active pattern 105 and/or between the first gate insulation pattern 220 and the first isolation pattern 110.

The first gate insulation pattern 220 may include a metal oxide having a high dielectric constant, e.g., hafnium oxide, tantalum oxide, zirconium oxide, etc. As used herein, the phrase “high dielectric constant” may mean a dielectric constant that is substantially equivalent to or greater than that of any of the aforementioned examples.

The first gate electrode 230 may include a metal nitride, e.g., titanium nitride, titanium aluminum nitride, tantalum nitride, tantalum aluminum nitride, etc., a metal alloy, e.g., titanium aluminum, titanium aluminum carbide, titanium aluminum oxynitride, titanium aluminum carbonitride, titanium aluminum oxycarbonitride, etc., a metal carbide, a metal oxynitride, a metal carbonitride, a metal oxycarbonitride, or a low electrical resistance metal, e.g., tungsten, aluminum, copper, tantalum.

The first capping pattern 240 may be formed on the first gate structure 250. Accordingly, the first capping pattern 240 may contact upper surfaces of the first gate electrode 230 and the first gate insulation pattern 220.

The first capping pattern 240 may include an electrically insulating nitride, e.g., silicon nitride.

The first gate spacer 160 may be formed on each of opposite sidewalls in the first direction D1 of the first gate structure 250, and thus an outer sidewall of the first gate insulation pattern 220 and a sidewall of the first capping pattern 240 may contact an inner sidewall of the first gate spacer 160.

The fin spacer 170 may be formed on each of opposite sidewalls in the second direction D2 of the first active pattern 105.

The first gate spacer 160 and the fin spacer 170 may include an electrically insulating nitride, e.g., silicon nitride (SiN), silicon oxynitride (SiON), silicon oxycarbonitride (SiOCN), etc.

The first source/drain layer 190 may be formed at each of opposite sides in the first direction D1 of the first gate structure 250, and may be interposed between ones of the first gate spacers 160 opposite in the first direction D1.

A cross-section in the second direction D2 of the first source/drain layer 190 may have a shape of a pentagon or a rhombus. In example embodiments, if a distance between neighboring ones of the first active patterns 105 in the second direction D2 is relatively small, corresponding ones of the first source/drain layers 190 on the neighboring ones of the first active patterns 105, respectively, may be merged with each other.

In an example embodiment, the first source/drain layer 190 may include single crystalline silicon-germanium doped with p-type impurities, and thus may serve as a source/drain region of a p-channel metal oxide semiconductor (PMOS) transistor. Alternatively, the first and second source/drain layer 190 may include single crystalline silicon or single crystalline silicon carbide doped with n-type impurities, and thus may serve as a source/drain region of an n-channel metal oxide semiconductor (NMOS) transistor.

The first source/drain layer 190 may be covered by the first insulating interlayer 200. The second insulating interlayer 260 may be formed on the first insulating interlayer 200, the first capping pattern 240 and the first gate spacer 160. The third insulating interlayer 270 may be formed on the second insulating interlayer 200 and the first contact plug 265.

Each of the first, second and third insulating interlayers 200, 260 and 270 may include an electrically insulating material, e.g., silicon oxycarbide (SiOC), silicon oxide (SiO₂), silicon nitride (SiN), silicon oxynitride (SiON), silicon carbonitride (SiCN), silicon oxycarbonitride (SiOCN), etc.

The first contact plug 265 may extend through the first and second insulating interlayers 200 and 260, and may contact an upper surface of the first source/drain layer 190.

The first contact plug 265 may include a conductive pattern and a barrier pattern covering a lower surface and a sidewall of the conductive pattern. The conductive pattern may include a metal, e.g., molybdenum, cobalt, tungsten, etc., and the barrier pattern may include a metal nitride, e.g., titanium nitride, tantalum nitride, tungsten nitride, etc.

In example embodiments, the second contact plug 290 may extend through the first capping pattern 240 and the second and third insulating interlayers 260 and 270, and may contact an upper surface of the first gate structure 250. The second contact plug 290 may include first and second conductive patterns 275 and 285 that are sequentially stacked in the third direction D3.

In example embodiments, a first thickness T1 in the third direction D3 of a central portion of the first conductive pattern 275 may be greater than a first width W1 in a horizontal direction substantially parallel to the upper surface of the substrate 100 of an edge portion of the first conductive pattern 275. As the first conductive pattern 275 has a sufficiently large thickness, when the second conductive pattern 285 is formed on the first conductive pattern 275, electrical characteristics of the first gate structure 250 under the first conductive pattern 275 might not deteriorate.

In addition, the second contact plug 290 might not include voids or seams therein, and thus may have enhanced electrical characteristics such as low electrical resistance.

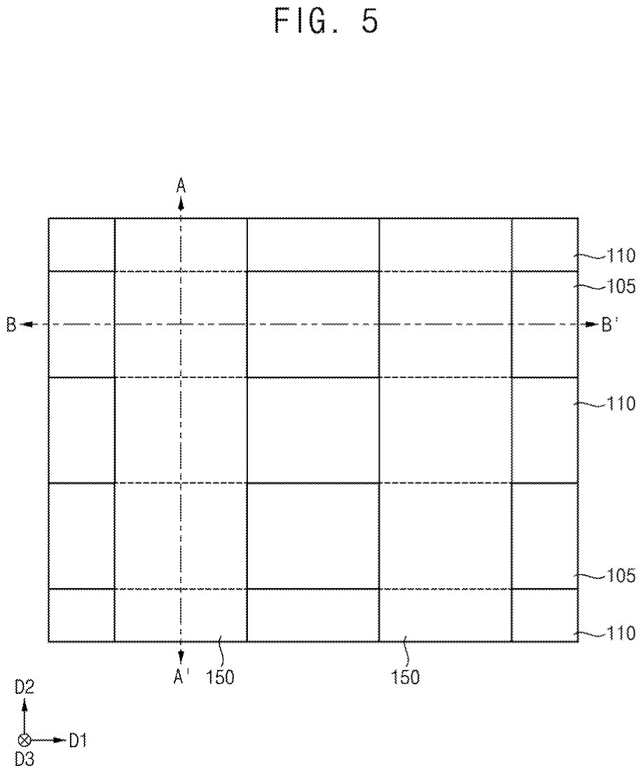

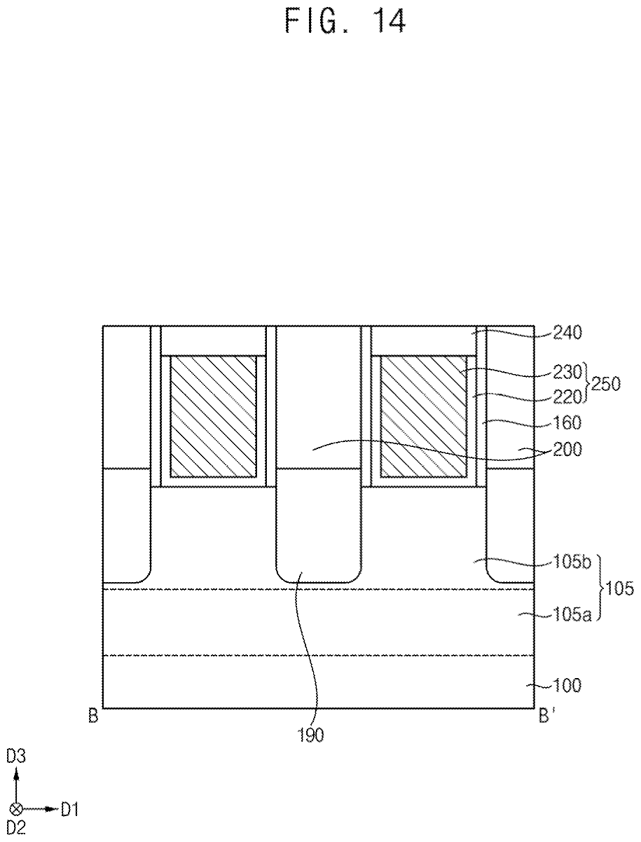

Characteristics of the second contact plug 290 is described in more detail in a method of manufacturing a semiconductor device described with reference to FIGS. 5 to 23.

In example embodiments, the first conductive pattern 275 may contact the upper surface of the first gate structure 250, and an upper surface of the central portion of the first conductive pattern 275 may be higher than upper surfaces of the edge portions of the first conductive pattern 275. A lower surface of the second conductive pattern 285 may contact the upper surface of the first conductive pattern 275, and thus, in accordance with the shape of the upper surface of the first conductive pattern 275, a lower surface of a central portion of the second conductive pattern 285 may be higher than lower surfaces of edge portions of the second conductive pattern 285.

Each of the first and second conductive patterns 275 and 285 may include, e.g., a metal, e.g., molybdenum, cobalt, tungsten, etc. The first and second conductive patterns 275 and 285 may include a material substantially the same as each other, or may include materials different from each other.

In example embodiments, the second conductive pattern 285 may further include impurities such as fluorine, chlorine, boron and/or silicon.

In example embodiments, a portion of the first capping pattern 240, a portion of the second insulating interlayer 260 and a portion of the third insulating interlayer 270 adjacent to the second contact plug 290 may each include the metal included in the first conductive pattern 275. The portion of the first capping pattern 240, the portion of the second insulating interlayer 260 and the portion of the third insulating interlayer 270 may be referred to as a first metal-containing portion 240a, a second metal-containing portion 260a, and a third metal-containing portion 270a, respectively.

Vias and wirings that may apply electrical signals to the first and second contact plugs 265 and 290 may be further formed thereon.

The semiconductor device may include the first gate structure 250 on the first active fin 105 serving as a channel and the first source/drain layers 190 on portions of the first active fin 105 adjacent to the first gate structure 250. Thus, the semiconductor device may include a finFET.

In the semiconductor device, the second contact plug 290 may include the first and second conductive patterns 275 and 285, and might not include a barrier pattern covering a lower surface and a sidewall of the first and second conductive patterns 275 and 285.

In general, a contact plug may include a barrier pattern and a conductive pattern of which a sidewall and a lower surface of the conductive pattern may be covered by the barrier pattern. If the contact plug has a large aspect ratio, a volume of the barrier pattern increases in a total volume of the contact plug, and thus a total electrical resistance of the contact plug may increase due to the barrier pattern which may include a relatively high electrical resistance material. However, in example embodiments, the second contact plug 290 may have a low total electrical resistance because the second contact plug 290 does not include the barrier pattern.

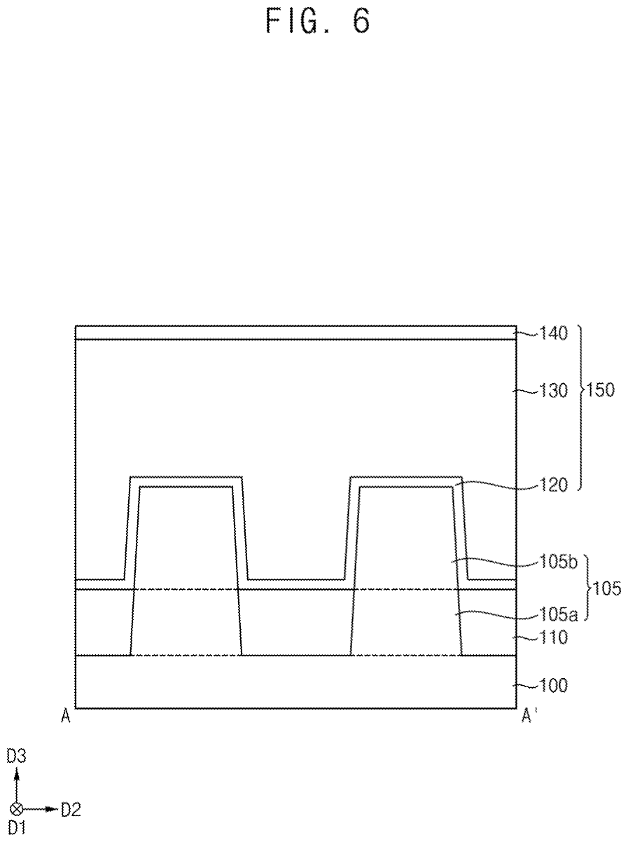

FIGS. 5 to 23 are plan views and cross-sectional views illustrating a method of manufacturing a semiconductor device in accordance with example embodiments. For example, FIGS. 5, 8, 12, 15 and 17 are the plan views, and FIGS. 6-7, 9-11, 13-14, 16 and 18-23 are the cross-sectional views.

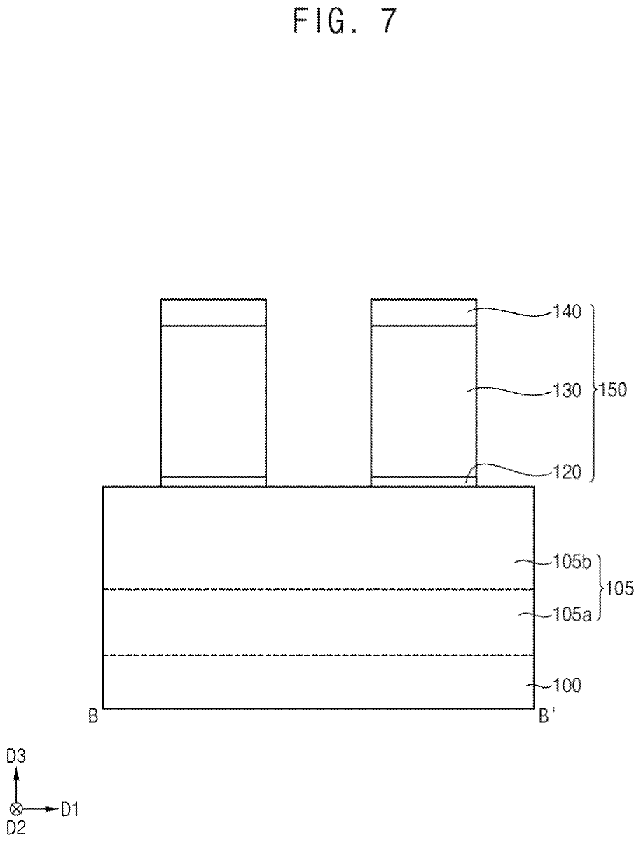

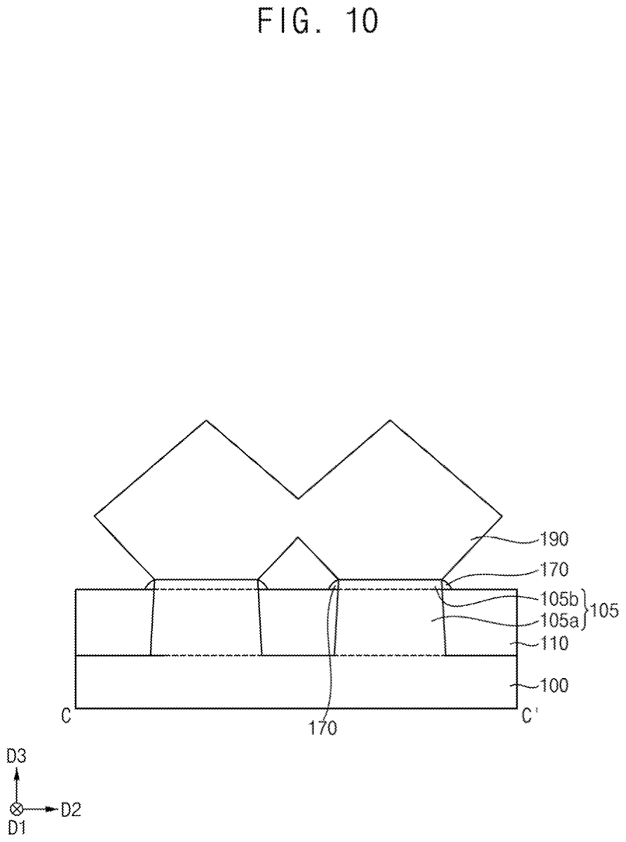

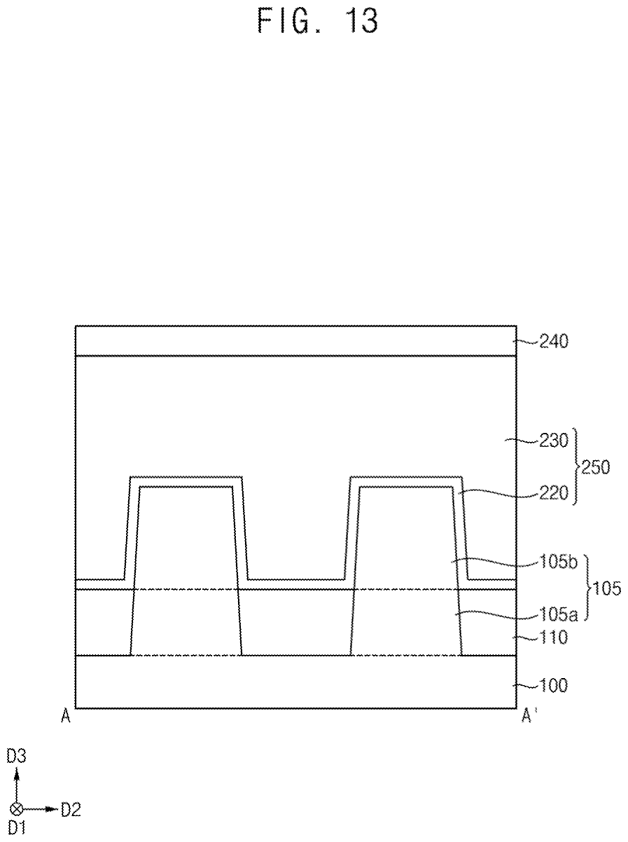

FIGS. 6 and 13 are cross-sectional views taken along lines A-A′ of corresponding plan views, respectively, FIGS. 7, 9, 11, 14, 16 and 18-23 are cross-sectional views taken along lines B-B′ of corresponding plan views, respectively, and FIG. 10 is a cross-sectional view taken along line C-C′ of a corresponding plan view.

Referring to FIGS. 5 to 7, an upper portion of a substrate 100 may be removed to form a first trench to define a first active pattern 105 on the substrate 100, and a first isolation pattern 110 may be formed in a lower portion of the first trench.

In example embodiments, the first isolation pattern 110 may be formed by forming a first isolation layer on the substrate 100 to fill the first trench, planarizing the first isolation layer until an upper surface of the substrate 100 is exposed, and removing an upper portion of the first isolation layer to expose an upper portion of the first trench.

The planarization process may include, e.g., a chemical mechanical polishing (CMP) process and/or an etch back process.

In example embodiments, the first active pattern 105 may extend in the first direction D1, and a plurality of first active patterns 105 may be spaced apart from each other in the second direction D2.

A first dummy gate structure 150 may be formed on the first active pattern 105 and the first isolation pattern 110. The first dummy gate structure 150 may include a first dummy gate insulation pattern 120, a first dummy gate electrode 130 and a first dummy gate mask 140 that are sequentially stacked.

The first dummy gate insulation pattern 120 may include an oxide, e.g., silicon oxide, the first dummy gate electrode 130 may include, e.g., polysilicon, and the first dummy gate mask 140 may include an electrically insulating nitride, e.g., silicon nitride.

In example embodiments, the first dummy gate structures 150 may extend in the second direction D2. A plurality of first dummy gate structures 150 may be spaced apart from each other in the first direction D1.

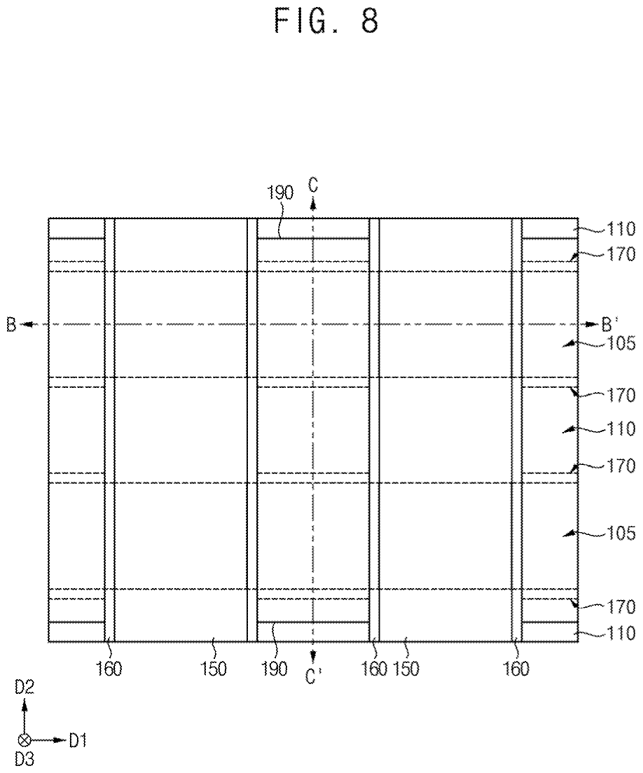

Referring to FIGS. 8 to 10, a first gate spacer 160 may be formed on each of opposite sidewalls in the first direction D1 of the first dummy gate structure 150. Additionally, a fin spacer 170 may be formed on each of opposite sidewalls in the second direction D2 of the first active pattern 105.

The first gate spacer 160 and the fin spacer 170 may be formed by forming a first spacer layer on the first active pattern 105, the first isolation pattern 110 and the first dummy gate structures 150, and anisotropically etching the first spacer layer. The first gate spacer 160 and the fin spacer 170 may include an electrically insulating nitride, e.g., silicon nitride (SiN), silicon oxynitride (SiON), silicon oxycarbonitride (SiOCN), etc.

Upper portions of the first active pattern 105 may be etched using the first dummy gate structure 150 and the first gate spacer 160 as an etching mask to form a first recess.

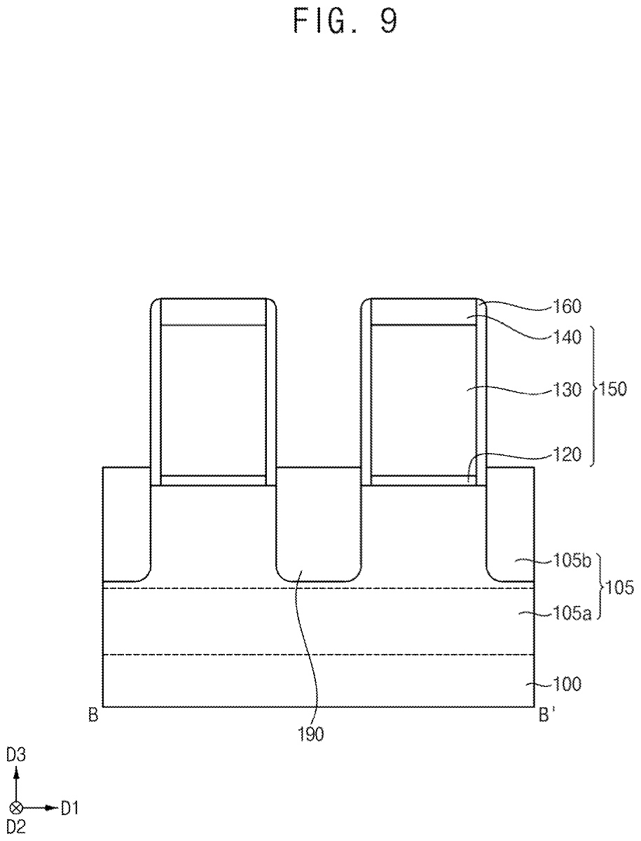

FIG. 9 shows that the first recess is formed by partially removing the first upper active pattern 105b, however, the inventive concept might not necessarily be limited thereto, and each of the first recess may be formed by partially removing the first lower active pattern 105a as well as the first upper active pattern 105b.

The anisotropic etching process of the first spacer layer and the etching process for forming the first recess may be performed in-situ.

A selective epitaxial growth (SEG) process may be performed by using an upper surface of the first active pattern 105 exposed by the first recess as a seed to form a first source/drain layer 190 on the first active pattern 105.

The SEG process may be performed using a silicon source gas, e.g., dichlorosilane (SiH₂Cl₂) gas, a germanium source gas, e.g., germane (GeH₄) gas to form a single-crystal silicon-germanium (SiGe) layer. A single crystalline silicon-germanium layer doped with p-type impurities may be formed as the first source/drain layer 190 by using a p-type impurity source gas, e.g., diborane (B₂H₆) gas together with the silicon source gas and the germanium source gas.

Alternatively, the SEG process may be performed using a silicon source gas, e.g., disilane (Si₂H₆) gas, a SiH₃CH₃ gas, etc., as a source gas to form a single crystal silicon carbide (SiC) layer. A single crystalline silicon carbide layer doped with n-type impurities may be formed as the first source/drain layer 190 by using an n-type impurity source gas, e.g., PH 3 together with the silicon source gas.

The first source/drain layer 190 may fill the first recess, and may further grow to contact a lower sidewall of the first gate spacer 160. The first source/drain layer 190 may grow in the horizontal direction as well as in a vertical direction, so as to have a cross-section taken along the second direction D2 having a shape of a pentagon or a rhombus. If a distance between ones of the first active patterns 105 neighboring in the second direction D2 is relatively small, corresponding ones of the first source/drain layers 190 grown from upper surfaces of the neighboring ones of the first active patterns 105, respectively, may be merged with each other.

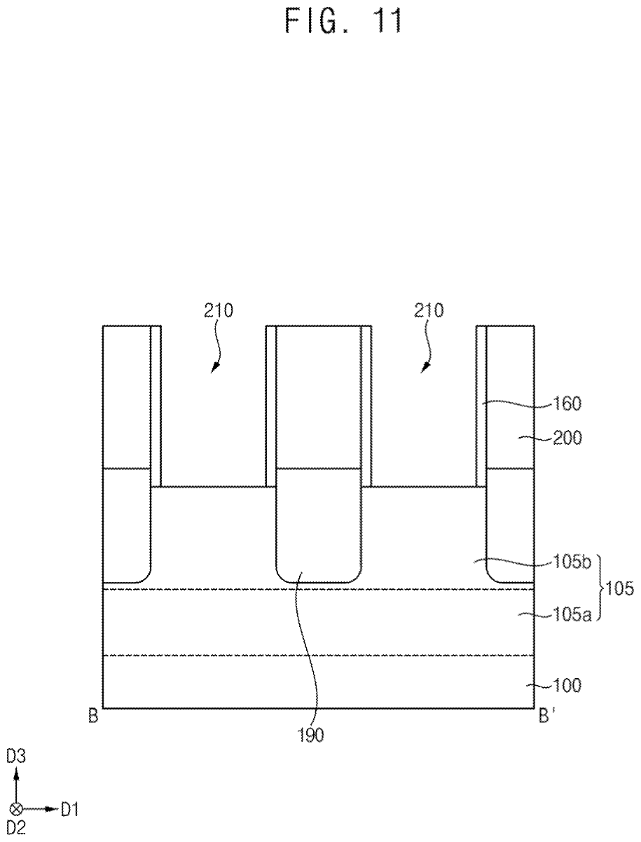

Referring to FIG. 11, a first insulating interlayer 200 may be formed on the first dummy gate structure 150, the first gate spacer 160, the fin spacer 170, the first source/drain layer 190 and the first isolation pattern 110 to have an upper surface higher than upper surfaces of the first dummy gate structure 150 and the first gate spacer 160.

A planarization process may be performed until an upper surface of the first dummy gate electrode 130 included in the first dummy gate structure 150 is exposed to remove an upper portion of the first insulating interlayer 200 and the first dummy gate mask 140 included in the first dummy gate structure 150, and an upper portion of the first gate spacer 160 may also be removed.

The first dummy gate electrode 130 and the first dummy gate insulation pattern 120 may be removed to form a first opening 210, which may expose upper surfaces of the first active pattern 105 and the first isolation pattern 110.

In example embodiments, the first dummy gate electrode 130 and the first dummy gate insulation pattern 120 may be removed by sequentially performing a dry etching process and a wet etching process. The wet etching process may be performed using, e.g., hydrofluoric acid (HF) as an etching solution.

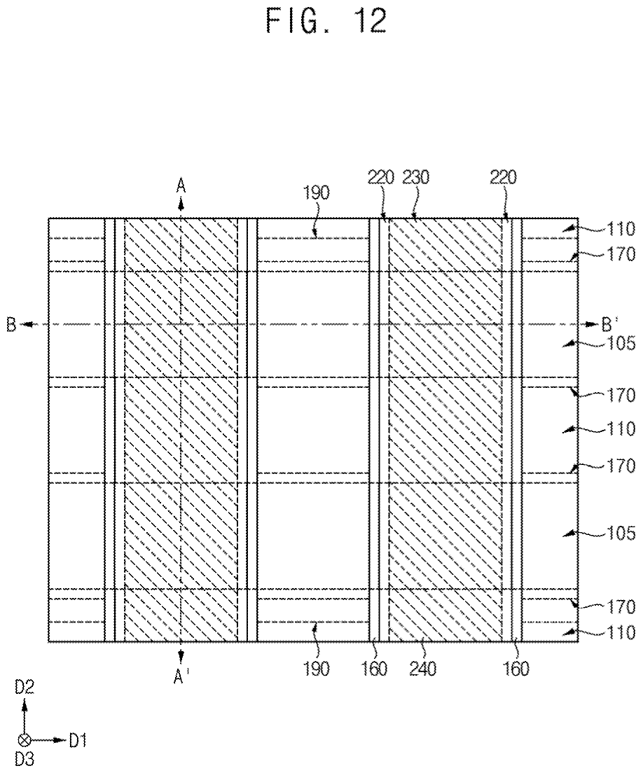

Referring to FIGS. 12 to 14, a first gate insulation layer may be formed on a bottom and a sidewall of the first opening 210 and an upper surface of the first insulating interlayer 200, a first gate electrode layer may be formed on the first gate insulation layer to fill a remaining portion of the first opening 210, and the first gate electrode layer and the first gate insulation layer may be planarized until the upper surface of the first insulating interlayer 200 is exposed.

Thus, a first gate electrode 230 and a first gate insulation pattern 220 covering a lower surface and a sidewall of the first gate electrode 230 may be formed in the first opening 210.

In an example embodiment, the first gate electrode layer may include a barrier layer and a gate conductive layer, and in this case, the first gate electrode 230 may include a barrier pattern and a gate conductive pattern.

Upper portions of the first gate electrode 230 and the first gate insulation pattern 220 may be removed to form a second recess, and a first capping pattern 240 may be formed in the second recess.

Thus, a first gate structure 250 including the first gate insulation pattern 220 on the upper surfaces of the first active pattern 105 and the first isolation pattern 110 and a lower inner sidewall of the first gate spacer 160 and the first gate electrode 230 on the first gate insulation pattern 220 in a lower portion of the first opening 210, and the first capping pattern 240 on the first gate structure 250 in an upper portion of the first opening 210 and contacting an upper inner sidewall of the first gate spacer 160 may be formed in the first opening 210.

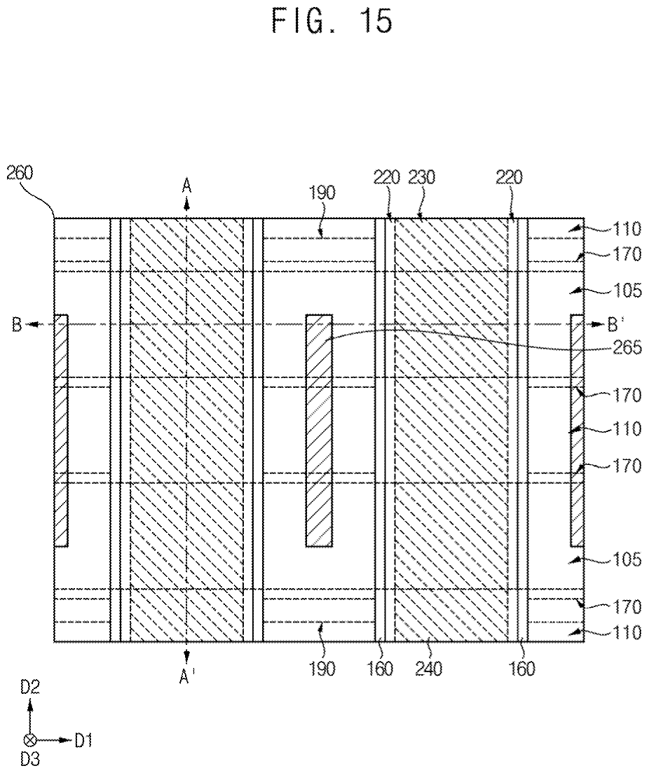

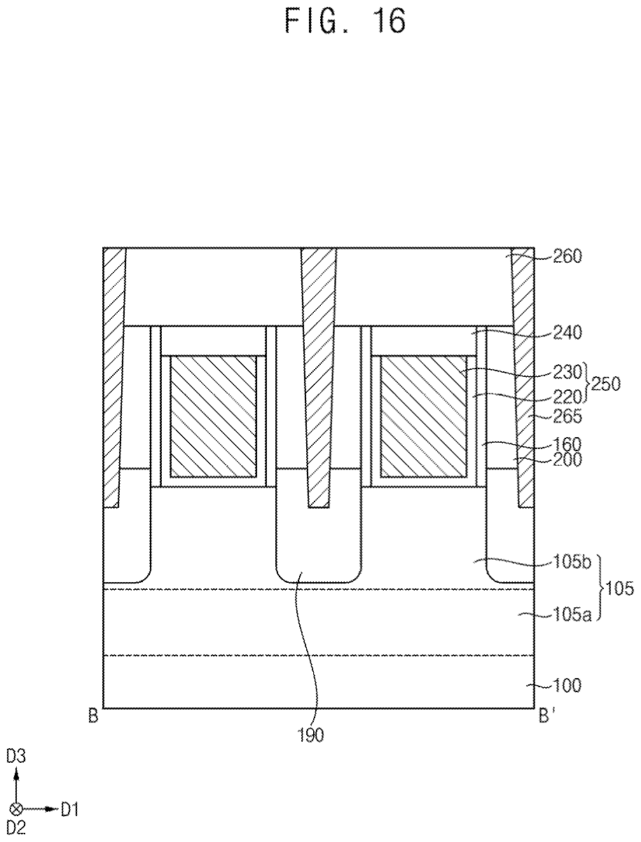

Referring to FIGS. 15 and 16, a second insulating interlayer 260 may be formed on the first capping pattern 240, the first gate spacer 160 and the first insulating interlayer 200, and the first and second insulating interlayers 200 and 260 may be partially removed to form a second opening exposing an upper surface of the first source/drain layer 190. A first contact plug 265 may be formed to fill the second opening.

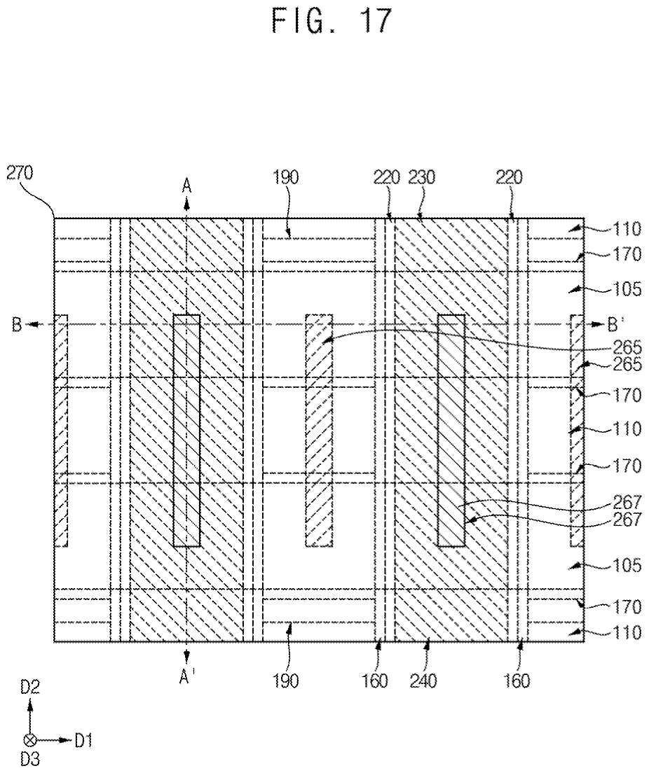

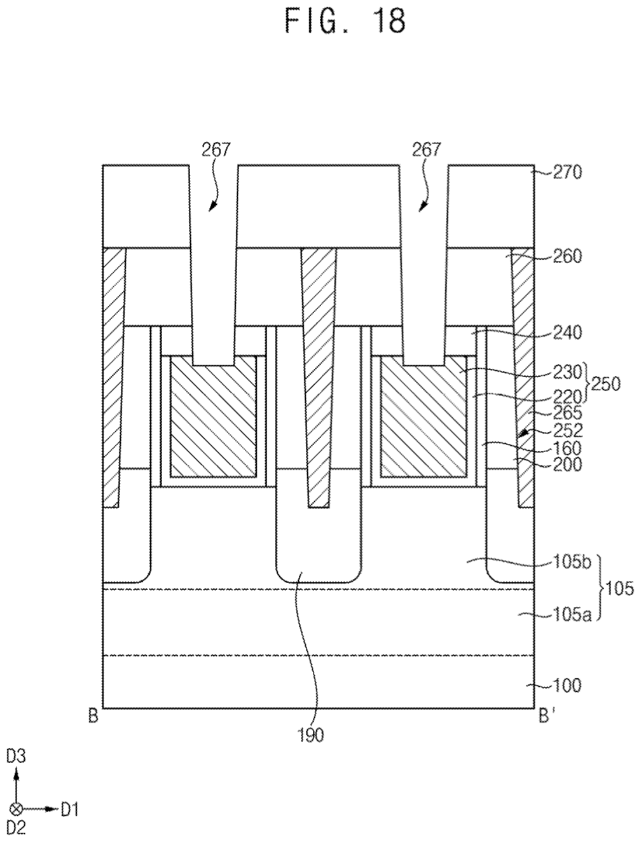

Referring to FIGS. 17 and 18, a third insulating interlayer 270 may be formed on the first contact plug 265 and the second insulating interlayer 260, and the second and third insulating interlayers 260 and 270 and the first capping patterns 240 may be partially removed to form a third opening 267 exposing an upper surface of the first gate structure 250.

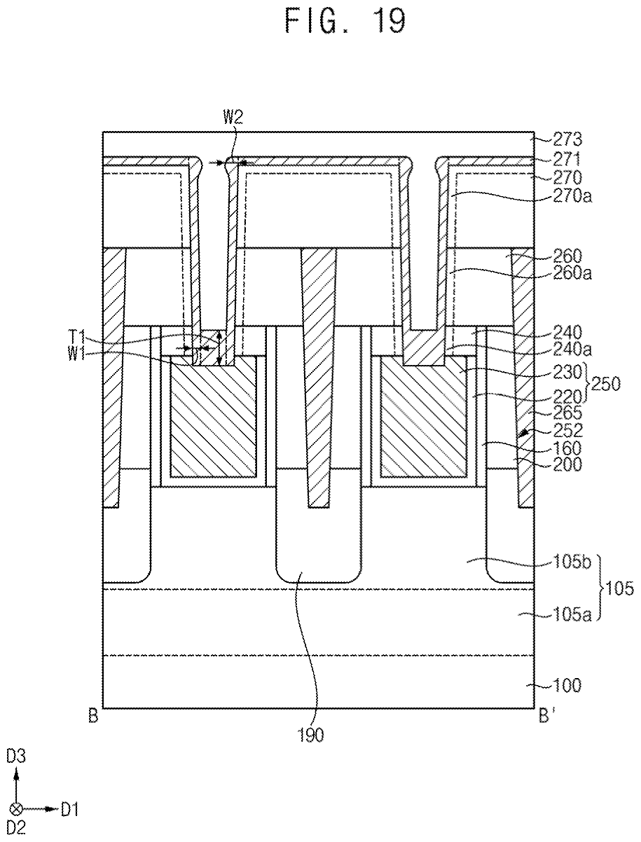

Referring to FIG. 19, a first conductive layer 271 may be formed on a bottom and a sidewall of the third opening 267 and an upper surface of the third insulating interlayer 270.

The first conductive layer 271 may have various thicknesses according to positions thereof. In example embodiments, a thickness of a first portion of the first conductive layer 271 on a bottom of the third opening 267 may be greater that a thickness of a second portion of the first conductive layer 271 on a sidewall of the third opening 267 and the upper surface of the third insulating interlayer 270. However, a third portion of the first conductive layer 271 on a sidewall of an inlet of the third opening 267 may have a greater thickness than a fourth portion of the first conductive layer 271 on sidewalls of other portions of the third opening 267.

In example embodiments, a first thickness T1 in the third direction D3 of the first portion of the first conductive layer 271 on the bottom of the third opening 267 may be greater than a first width W1 in the horizontal direction of the fourth portion of the first conductive layer 271 on the sidewalls of the other portions of the third opening 267. A second width W2 in the horizontal direction of the third portion of the first conductive layer 271 on the sidewall of the inlet of the third opening 267 may be greater than the first width W1 in the horizontal direction of the fourth portion of the first conductive layer 271 on the sidewalls of the other portions of the third opening 267.

FIG. 19 shows that an upper surface of a portion of the first conductive layer 271 on a central portion of the bottom of the third opening 267 is lower than an upper surface of the first capping pattern 240, however, the inventive concept might not be necessarily limited thereto, and the upper surface of the portion of the first conductive layer 271 on the central portion of the bottom of the third opening 267 may be higher than the upper surface of the first capping pattern 240.

In example embodiments, the first conductive layer 271 may be formed by a physical vapor deposition (PVD) process such as a sputtering process, and may be formed to include a metal.

During the PVD process, the metal included in the first conductive layer 271 may diffuse into a portion of the first capping pattern 240 and portions of the second and third insulating interlayers 260 and 270 adjacent to the bottom and the sidewall of the third opening 267. Thus, the portion of the first capping pattern 240 and the portions of the second and third insulating interlayers 260 and 270 may be referred to as a first metal-containing portion 240a, a second metal-containing portion 260a, and a third metal-containing portion 270a, respectively.

A sacrificial layer 273 may be formed on the first conductive layer 271 to fill the third opening 267.

In example embodiments, the sacrificial layer 273 may include a material having an etch selectivity with respect to the first conductive layer 271, e.g., a material containing carbon (C).

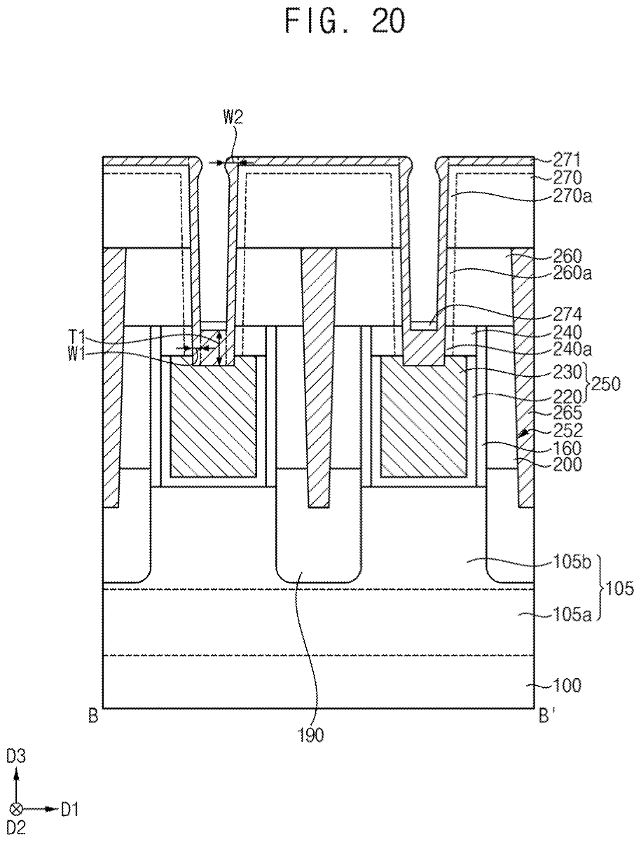

Referring to FIG. 20, an upper portion of the sacrificial layer 273 may be removed to form a sacrificial pattern 274.

The sacrificial pattern 274 may remain on the portion of the first conductive layer 271 on the central portion of the bottom of the third opening 267, and thus the second portion of the first conductive layer 271 on the sidewall of the third opening 267 and the upper surface of the third insulating interlayer 270 may be mostly exposed. FIG. 20 shows that an upper surface the sacrificial pattern 274 is higher than the upper surface of the first capping pattern 240, however, the inventive concept might not be necessarily limited thereto, and the upper surface of the sacrificial pattern 274 may be lower than the upper surface of the first capping pattern 240.

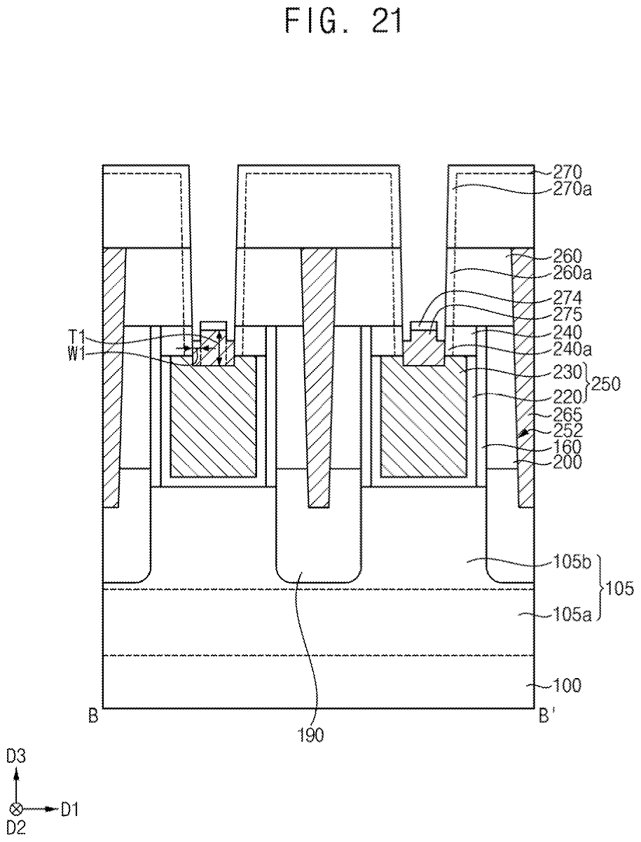

Referring to FIG. 21, the first conductive layer 271 may be etched using the sacrificial pattern 274 as an etching mask so that a portion of the first conductive layer 271 not covered by the sacrificial pattern 274 may be removed. Accordingly, a sidewall of the first capping pattern 240, a sidewall of the second insulating interlayer 260 and a sidewall and the upper surface of the third insulating interlayer 270 may be exposed, and the first conductive layer 271 may be transformed to a first conductive pattern 275.

In example embodiments, an upper surface of a portion of the first conductive pattern 275 on an edge portion of the bottom of the third opening 267 may be lower than an upper surface of a portion of the first conductive pattern 275 on the central portion of the bottom of the third opening 267.

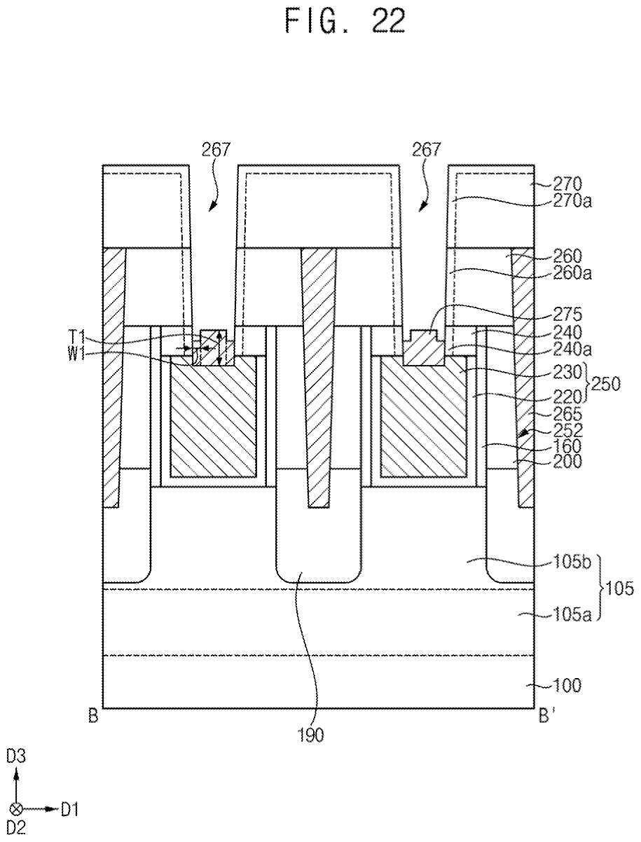

Referring to FIG. 22, the sacrificial pattern 274 may be removed.

The sacrificial pattern 274 may be removed by, e.g., a wet etching process and/or a dry etching process.

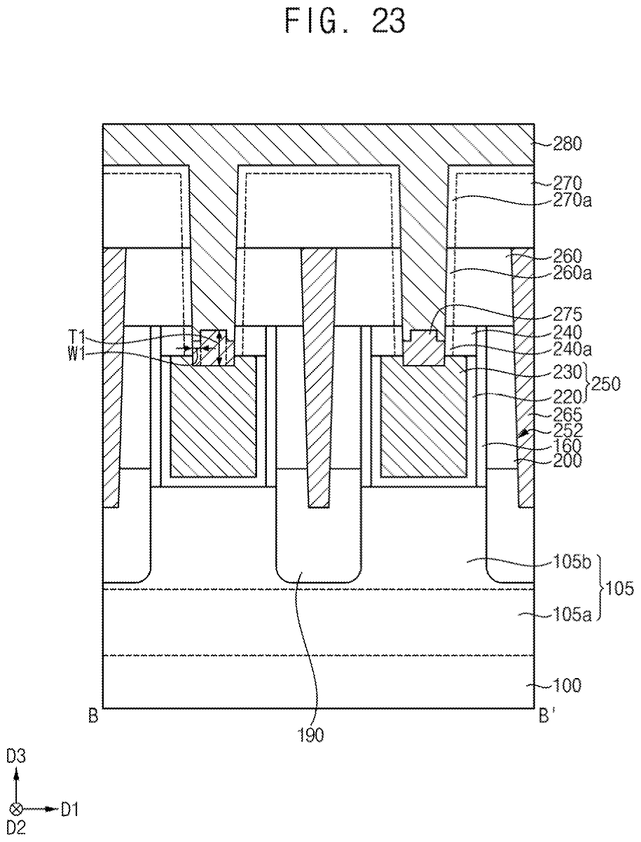

Referring to FIG. 23, a second conductive layer 280 may be formed on the first conductive pattern 275 and the third insulating interlayer 270 to fill the third opening 267.

In example embodiments, the second conductive layer 280 may be formed by a selective chemical vapor deposition (CVD) process using the first conductive pattern 275 as a seed.

In example embodiments, the selective CVD process may be performed using a source gas, e.g., WF₆ or WCl₆, and a reduction gas, e.g., B₂H₆ or SiH₄. Accordingly, the second conductive layer 280 may include impurities such as fluorine (F), chlorine (Cl), boron (B), and/or silicon (Si), in addition to a metal, e.g., tungsten.

As illustrated above, the second width W2 of the third portion of the first conductive layer 271 on the sidewall of the inlet of the third opening 267 may be greater than the first width W1 of the fourth portion of the first conductive layer 271 on the sidewalls of the other portions of the third opening 267. Accordingly, if the selective CVD process is performed without partially removing the first conductive layer 271 illustrated with reference to FIG. 21, the second conductive layer 280 might not only grow in the third direction D3 from the first portion of the first conductive layer 271 on the bottom of the third opening 267, but may also grow in the horizontal direction from the second portion of the first conductive layer 271 on the sidewall of third opening 267. Thus, the inlet of the third opening 267 may be blocked before the third opening 267 is sufficiently filled with the second conductive layer 280.

However, in example embodiments, the selective CVD process may be performed after the first conductive layer 271 is partially removed, and thus the second conductive layer 280 may grow only in the third direction D3. Accordingly, voids or seams might not be formed in the second conductive layer 280, and a contact plug including the second conductive layer 280 may have enhanced electrical characteristics such as reduced electrical resistance.

In addition, the first thickness T1 of the first portion of the first conductive layer 271 on the bottom of the third opening 267 may be greater that the thickness of the second portion of the first conductive layer 271 on the sidewall of the third opening 267. Accordingly, the first conductive pattern 275 remaining on the bottom of the third opening 267 may have a sufficient thickness. Thus, during the selective CVD process, fluorine (F) or chlorine (Cl) may be prevented from diffusing into the first gate structure 250, and thus the deterioration of the electrical characteristics of the first gate structure 250 may be prevented.

Referring to FIGS. 1 to 4 again, a planarization process may be performed on the second conductive layer 280 until an upper surface of the third insulating interlayer 270 is exposed.

Accordingly, the second conductive layer 280 may be transformed into a second conductive pattern 285, and the first and second conductive patterns 275 and 285 that are sequentially stacked in the third direction D3 may form a second contact plug 290.

The third metal-containing portion 270a may be removed during the planarization process.

As illustrated above, the portion of the first conductive layer 271 on the sidewall of the third opening 267 may be removed to form the first conductive pattern 275 on the bottom of the third opening 267, and the second conductive layer 280 may be grown in the third direction D3 by performing the selective CVD process using the first conductive pattern 275 as a seed so that the formation of voids or seams may be prevented. Accordingly, the second contact plug 290 including the first conductive pattern 275 and the second conductive pattern 285, which may be formed by removing an upper portion of the second conductive layer 280, may have enhanced electrical characteristics such as low electrical resistance.

In addition, due to the first conductive pattern 275 having a sufficiently large thickness, fluorine (F) or chlorine (Cl) included in the source gas used for forming the second conductive layer 280 may be prevented from diffusing into the first gate structure 250.

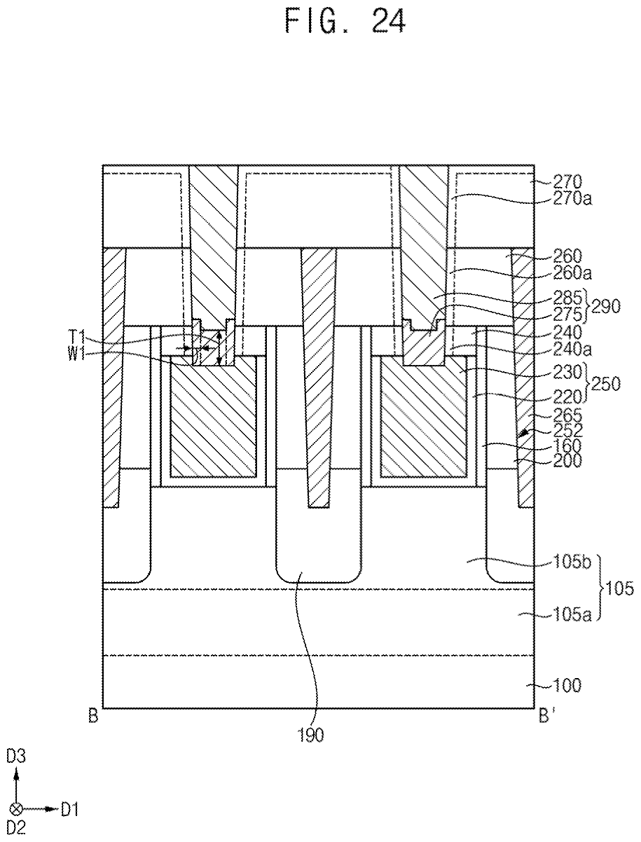

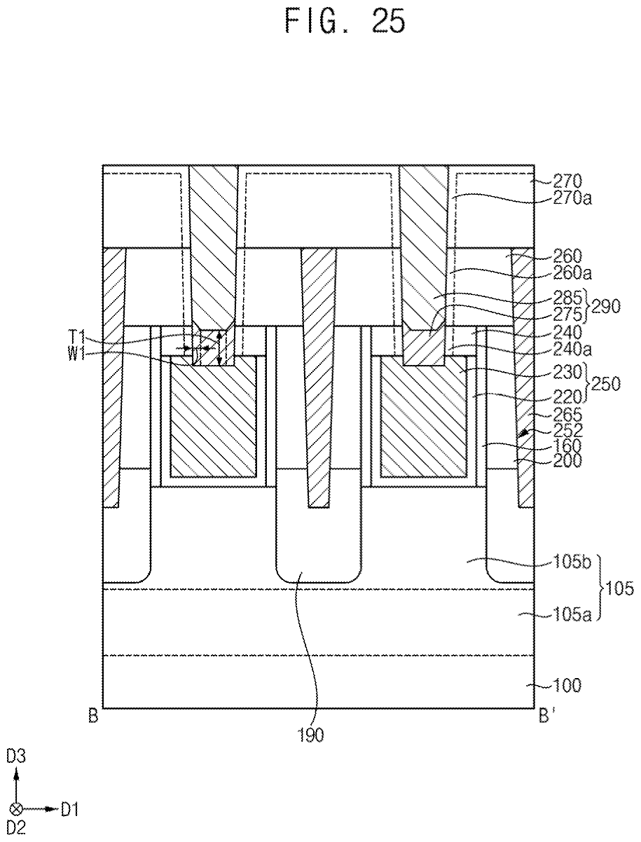

FIGS. 24 and 25 are cross-sectional views illustrating semiconductor devices in accordance with example embodiments, which may correspond to FIG. 3.

These semiconductor devices may be substantially the same as or similar to that of FIGS. 1 to 4, except for the shape of an upper surface of the first conductive pattern 275 and a lower surface of the second conductive pattern 285, and thus to the extent that an element is not described in detail, it may be assumed that the element is at least similar to a corresponding element that has been described elsewhere within the present disclosure.

Referring to FIG. 24, an upper surface of an edge portion of the first conductive pattern 275 may be higher than an upper surface of a central portion of the first conductive pattern 275.

A lower surface of the second conductive pattern 285 may contact an upper surface of the first conductive pattern 275, and may have a shape in accordance with the shape of the upper surface of the first conductive pattern 275. Accordingly, a lower surface of a central portion of the second conductive pattern 285 may be lower than a lower surface of an edge portion of the second conductive pattern 285.

In example embodiments, the first width W1 of the edge portion of the first conductive pattern 275 may be substantially constant at a height that is higher than the upper surface of the central portion of the first conductive pattern 275.

Referring to FIG. 25, the upper surface of the edge portion of the first conductive pattern 275 may be higher than the upper surface of the central portion of the first conductive pattern 275.

In example embodiments, the first width W1 of the edge portion of the first conductive pattern 275 may decrease in the third direction D3 from a bottom to a top thereof at the height that is higher than the upper surface of the central portion of the first conductive pattern 275. Accordingly, a sidewall of the edge portion of the first conductive pattern 275 at the height that is higher than the upper surface of the central portion of the first conductive pattern 275 may be inclined with respect to the upper surface of the substrate 100.

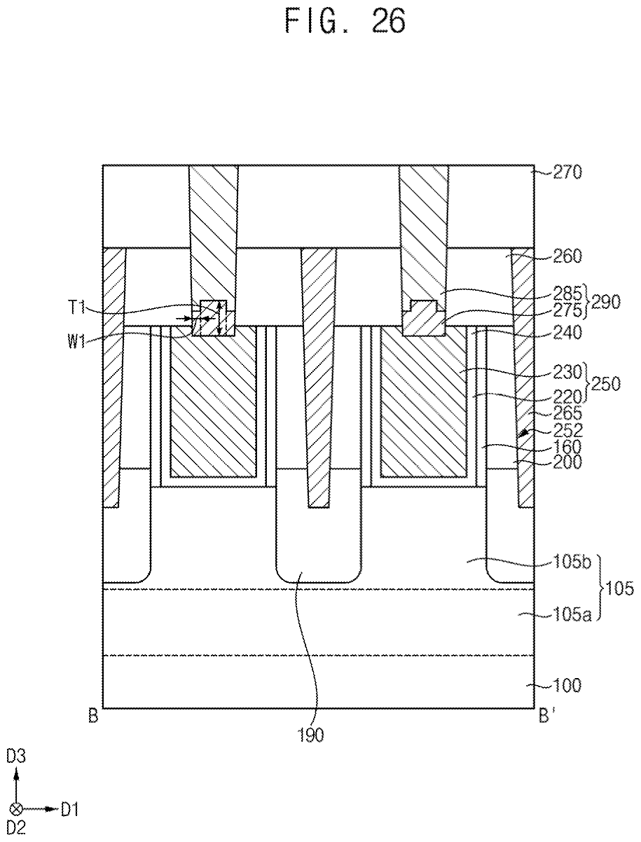

FIG. 26 is a cross-sectional view illustrating a semiconductor device in accordance with example embodiments, which may correspond to FIG. 3.

This semiconductor device may be substantially the same as or similar to that of FIGS. 1 to 4, except for not including the first capping pattern 240, and thus to the extent that an element is not described in detail, it may be assumed that the element is at least similar to a corresponding element that has been described elsewhere within the present disclosure.

Referring to FIG. 26 the first capping pattern 240 might not be formed on the first gate structure 250, and thus the second contact plug 290 may extend through the second and third insulating interlayers 260 and 270 to contact the upper surface of the first gate structure 250.

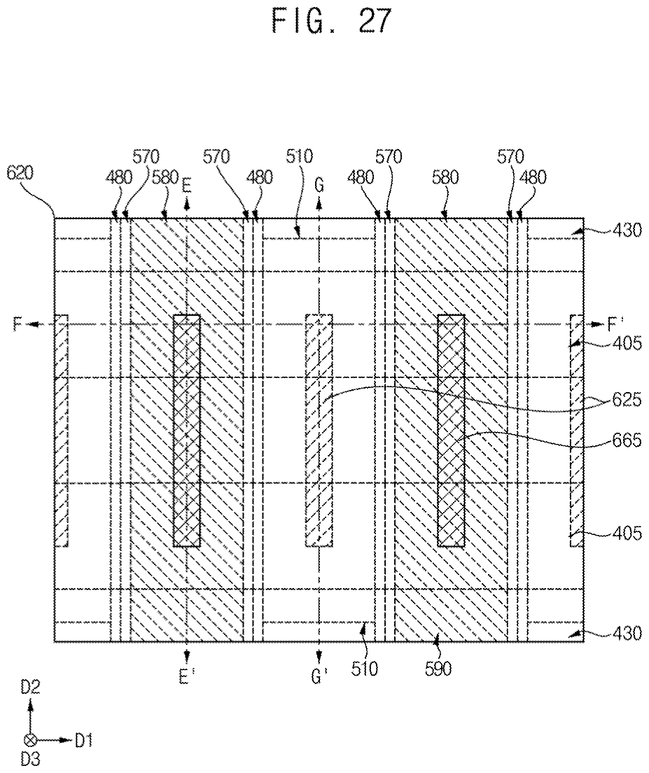

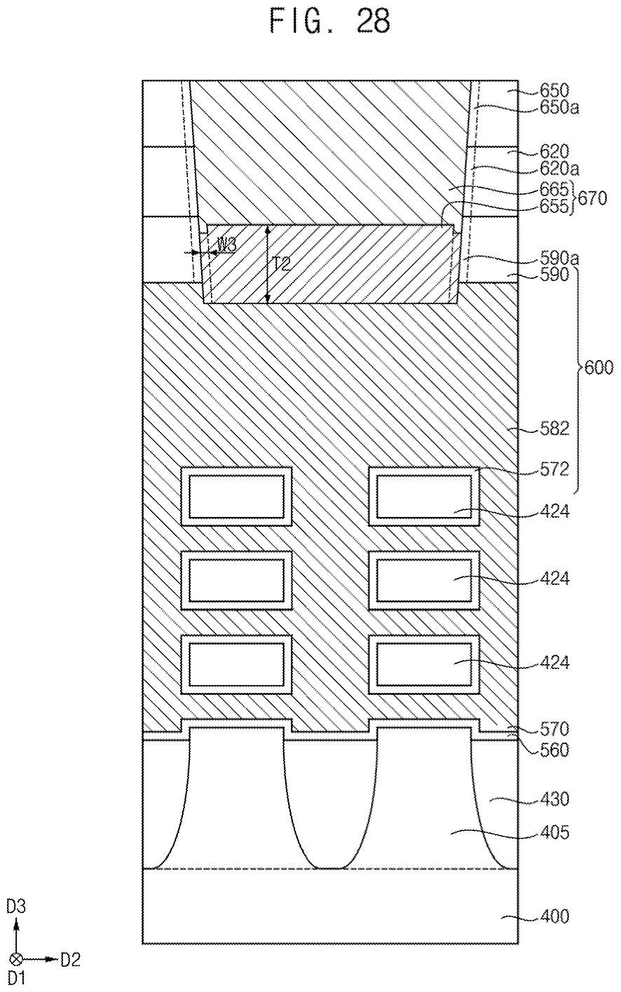

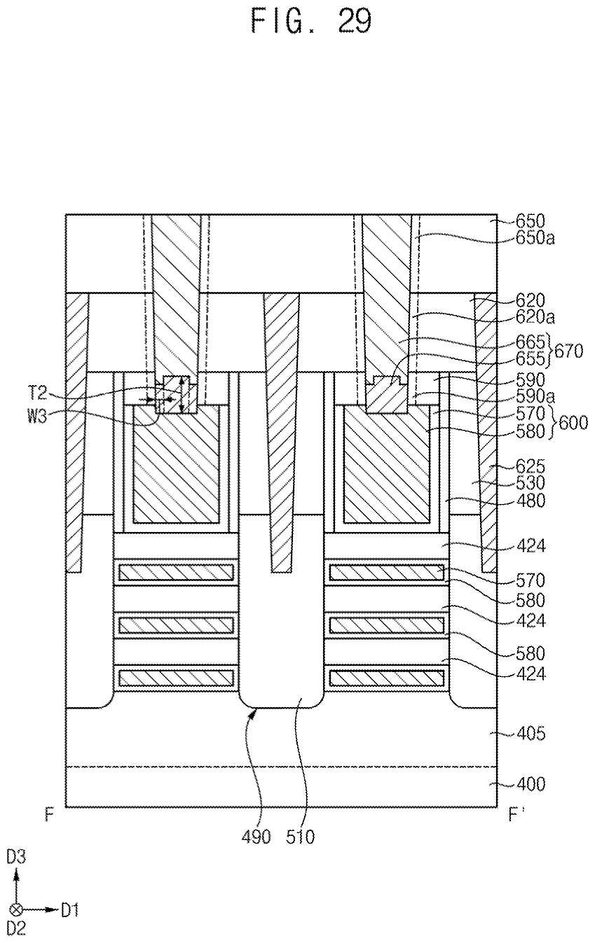

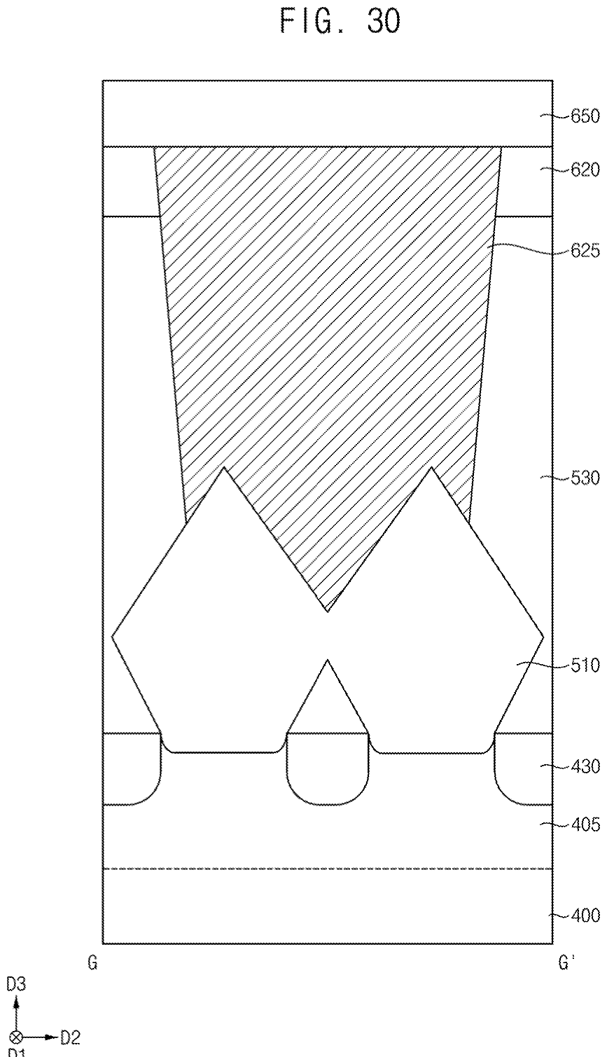

FIGS. 27 to 30 are a plan view and cross-sectional views illustrating a semiconductor device in accordance with example embodiments. For example, FIG. 27 is the plan view, FIG. 28 is a cross-sectional view taken along line E-E′ of FIG. 27, FIG. 29 is a cross-sectional view taken along line F-F′ of FIG. 27, and FIG. 30 is a cross-sectional view taken along line G-G′ of FIG. 27.

This semiconductor device may include elements substantially the same as or similar to those illustrated with reference to FIGS. 1 to 4, and thus to the extent that an element is not described in detail, it may be assumed that the element is at least similar to a corresponding element that has been described elsewhere within the present disclosure.

As illustrated below, the semiconductor device may be a multi-bridge channel field effect transistor (MBCFET) including semiconductor patterns 424 spaced apart from each other in the third direction D3 and serving as channels, respectively. Thus, other elements except for the semiconductor patterns 424 may lave similar functions and structures to corresponding elements included in the finFET of FIGS. 1 to 4.

Referring to FIGS. 27 to 30, the semiconductor device may include a second gate structure 600 and a fourth contact plug 670 on a substrate 400.

Also, the semiconductor device may include a second active pattern 405, a second gate spacer 480, a second source/drain layer 510, a second capping pattern 590, a third contact plug 625, and fourth to sixth insulating interlayers 530, 620 and 650.

The second active pattern 405 and the second isolation pattern 430 may correspond to the first active pattern 105 and the first isolation pattern 110, respectively, of FIGS. 1 to 4.

In example embodiments, a plurality of semiconductor patterns 424 may be formed at a plurality of levels, respectively, and may be spaced apart from each other in the third direction D3 from an upper surface of the second active pattern 405. Each of the plurality of semiconductor patterns 424 may extend in the first direction D1. FIGS. 28 and 29 show three semiconductor patterns 424 at three levels, respectively, however, the inventive concept might not necessarily be limited thereto.

In example embodiments, the semiconductor pattern 424 may be a nano-sheet or nano-wire including a semiconductor material, e.g., silicon, germanium, etc. In example embodiments, the semiconductor pattern 424 may serve as a channel in a transistor, and thus may also be referred to as a channel.

The second gate structure 600 and the second gate spacer 480 may correspond to the first gate structure 250 and the first gate spacer 160, respectively, of FIGS. 1 to 4.

Thus, the second gate structure 600 may extend in the second direction D2 on the second active pattern 405 and the second isolation pattern 430, and may include a second gate insulation pattern 570 and a second gate electrode 580.

The second gate structure 600 may at least partially surround a central portion in the first direction D1 of each of the semiconductor patterns 424, and may cover lower and upper surfaces and opposite sidewalls in the second direction D2 of each of the semiconductor patterns 424.

Thus, the second gate insulation pattern 570 may be formed on a surface of each of the semiconductor patterns 424, upper surfaces of the second active pattern 405 and the second isolation pattern 430, a sidewall of the second source/drain layer 510 and an inner sidewall of the second gate spacer 480, and the second gate electrode 580 may fill a space between the semiconductor patterns 424 spaced apart from each other in the third direction D3, a space between the second active pattern 405 and a lowermost one of the semiconductor pattern 424, and a space between the second gate spacers 480 on an uppermost one of the semiconductor patterns 424.

The second capping pattern 590 may correspond to the first capping pattern 240 of FIGS. 1 to 4. Accordingly, the second capping pattern 590 may be formed on the second gate structure 600, and may contact upper surfaces of the second gate electrode 580 and the second gate insulation pattern 570.

The second source/drain layer 510 may correspond to the first source/drain layer 190 of FIGS. 1 to 4. The second source/drain layer 510 may be formed in a third recess on a portion of the second active pattern 405 adjacent to the second gate structure 600.

The third contact plug 625 may correspond to the first contact plug 265 of FIGS. 1 to 4. Accordingly, the third contact plug 625 may extend through the fourth and fifth insulating interlayers 530 and 620 to contact an upper surface of the second source/drain layer 510.

The fourth contact plug 670 may correspond to the second contact plug 290 of FIGS. 1 to 4. Accordingly, the fourth contact plug 670 may extend through the second capping pattern 590 and the fifth and sixth insulating interlayers 620 and 650 to contact an upper surface of the second gate structure 600, and may include third and fourth conductive patterns 655 and 665 that are sequentially stacked. The third and fourth conductive patterns 655 and 665 may correspond to the first and second conductive patterns 275 and 285, respectively, of FIGS. 1 to 4.

In example embodiments, a second thickness T2 in the third direction D3 of a central portion of the third conductive pattern 655 may be greater than a third width W3 in the horizontal direction of an edge portion of the third conductive pattern 655.

In example embodiments, the third conductive pattern 655 may contact the upper surface of the second gate structure 600, and an upper surface of the central portion of the third conductive pattern 655 may be higher than an upper surface of the edge portion of the third conductive pattern 655.

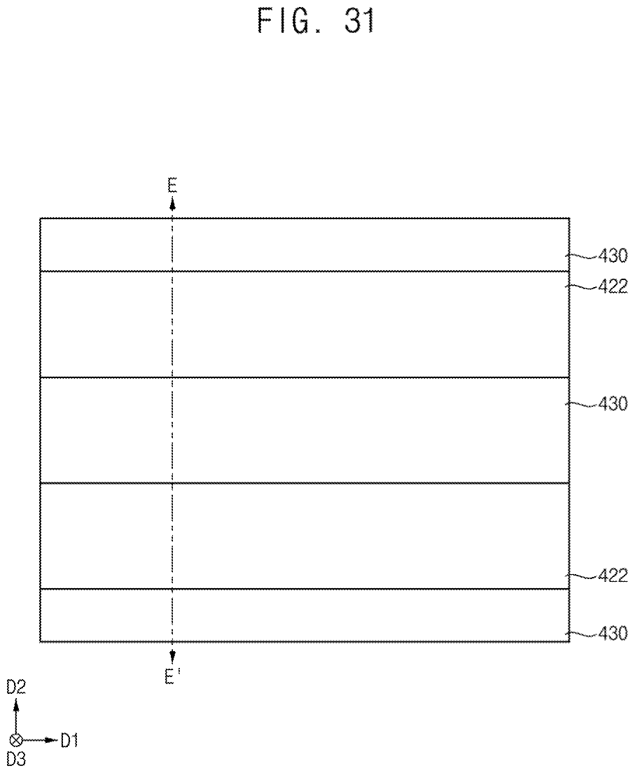

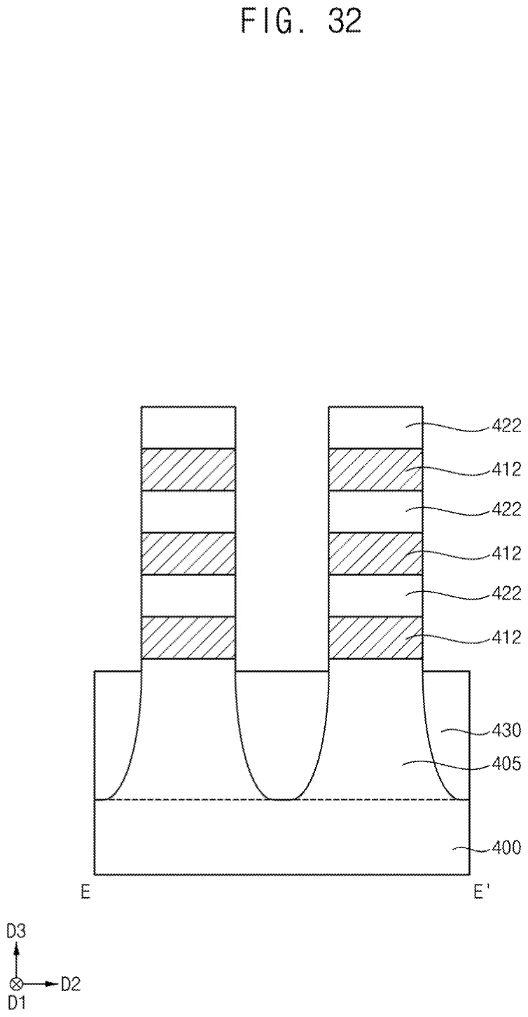

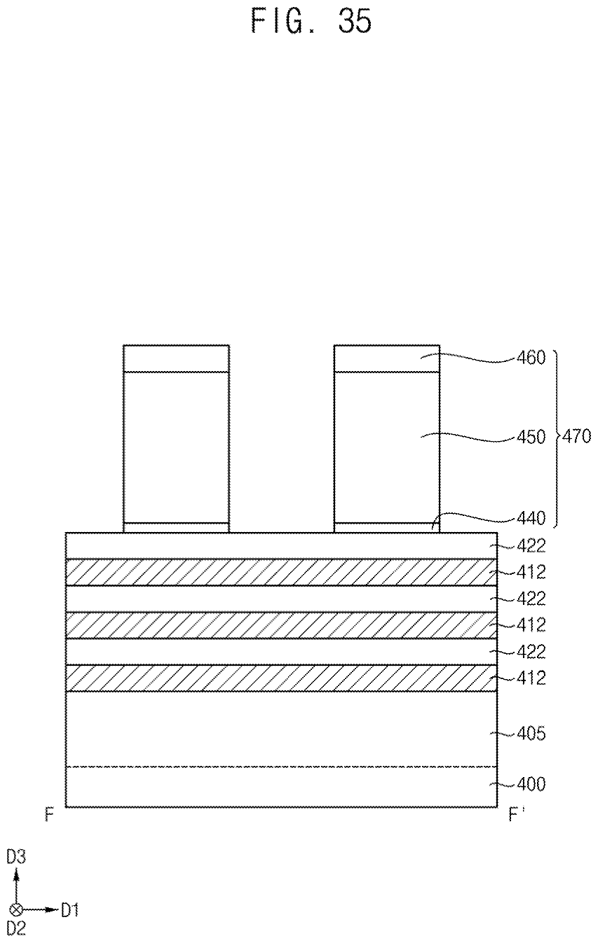

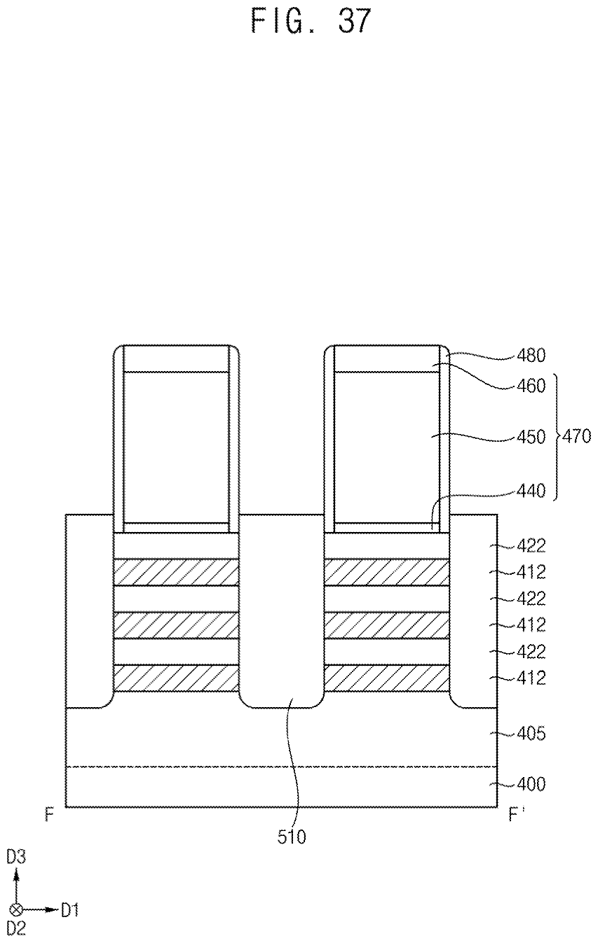

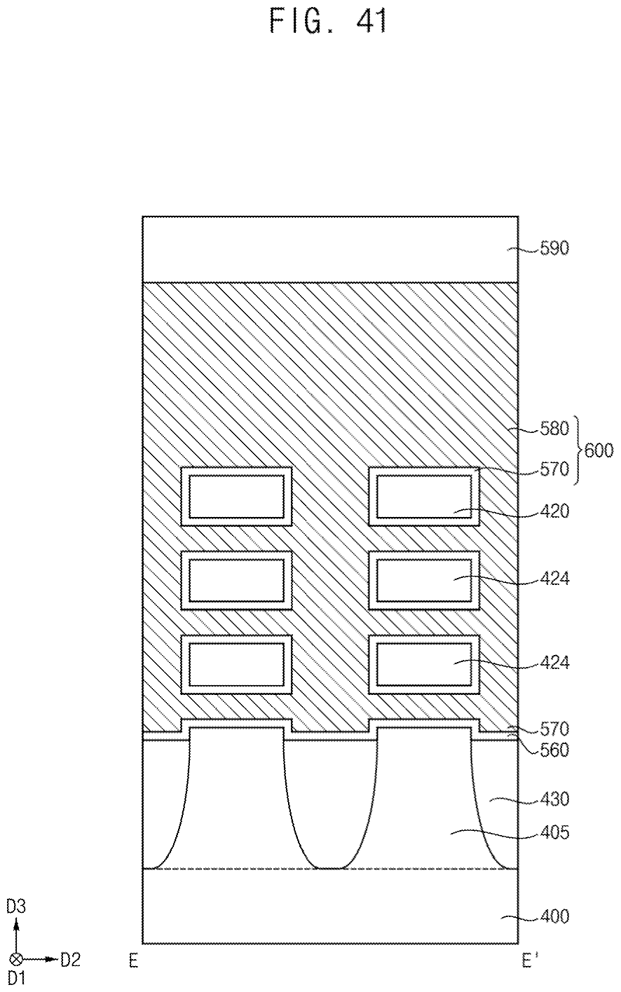

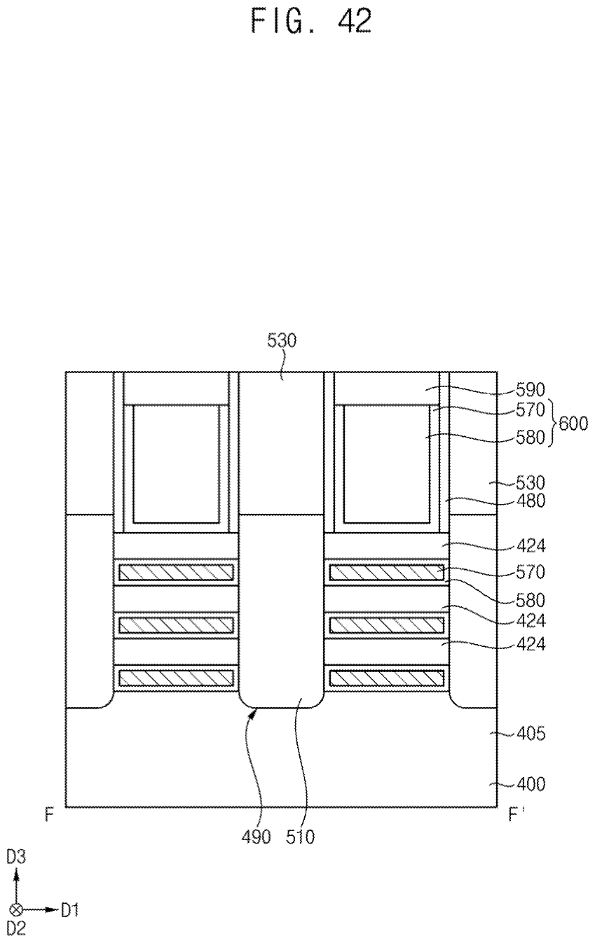

FIGS. 31 to 42 are plan views and cross-sectional views illustrating a method of manufacturing a semiconductor device in accordance with example embodiments. For example, FIGS. 31, 33, 36 and 40 are the plan views, and FIGS. 32, 34-35, 37-39 and 41-45 are the cross-sectional views.

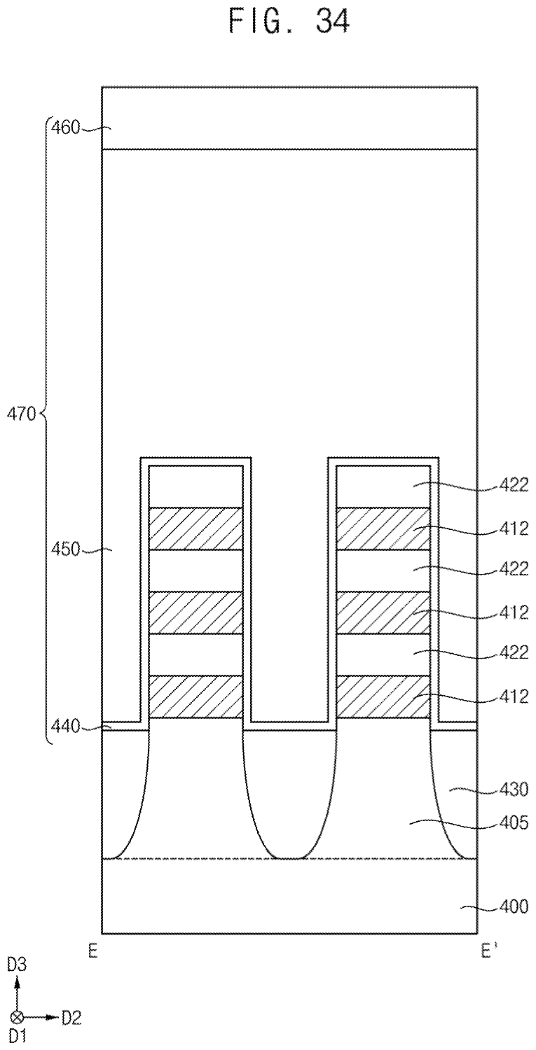

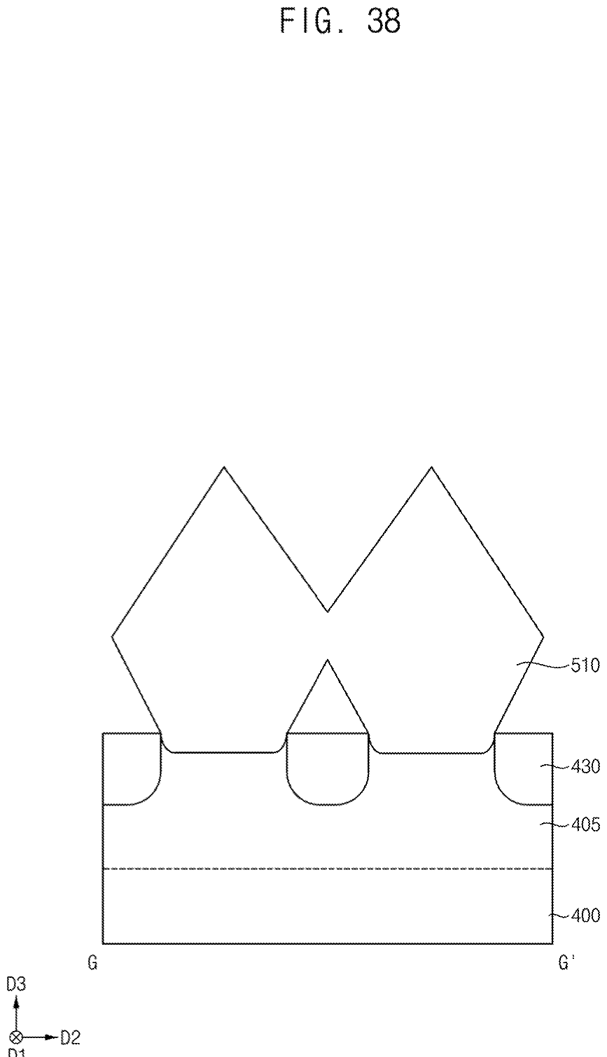

FIGS. 32, 35 and 41 are cross-sectional views taken along lines E-E′ of corresponding plan views, respectively, FIGS. 34, 37, 39 and 42-45 are cross-sectional views taken along lines F-F′ of corresponding plan views, respectively, and FIG. 38 is a cross-sectional view taken along line G-G′ of a corresponding plan view.

This method may include processes substantially the same as or similar to those illustrated with reference to FIGS. 5 to 23 and FIGS. 1 to 4, and thus to the extent that an element is not described in detail, it may be assumed that the element is at least similar to a corresponding element that has been described elsewhere within the present disclosure.

Referring to FIGS. 31 and 32, a sacrificial layer and a semiconductor layer may be alternately and repeatedly stacked on a substrate 400, a first etching mask extending in the first direction D1 may be formed on an uppermost one of the semiconductor layers, and the semiconductor layers, the sacrificial layers and an upper portion of the substrate 400 may be etched using the third etching mask.

Thus, a second active pattern 405 extending in the first direction D1 may be formed on the substrate 400, and a fin structure including sacrificial lines 412 and semiconductor lines 422 alternately and repeatedly stacked in the third direction D3 may be formed on the second active pattern 405. In example embodiments, a plurality of fin structures may be spaced apart from each other in the second direction D2 on the substrate 400.

FIG. 32 shows three sacrificial lines 412 and three semiconductor lines 422 at three levels, respectively, however, the inventive concept might not necessarily be limited thereto. The sacrificial lines 412 may include a material having an etching selectivity with respect to the substrate 400 and the semiconductor lines 422, e.g., silicon-germanium.

A second isolation pattern 430 may be formed on the substrate 400 and may cover a sidewall of the second active pattern 405.

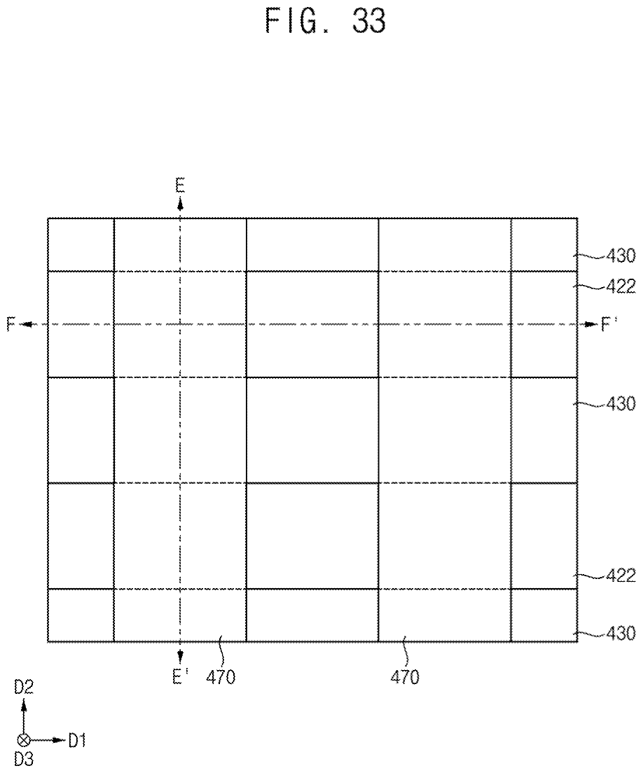

Referring to FIGS. 33 to 35, a second dummy gate structure 470 may be formed to partially cover the fin structure and the second isolation pattern 430.

For example, a second dummy gate insulation layer, a second dummy gate electrode layer and a second dummy gate mask layer may be sequentially formed on the fin structure and the second isolation pattern 430, a second etching mask extending in the second direction D2 may be formed on the second dummy gate mask layer, and the second dummy gate mask layer may be etched using the second etching mask to form a second dummy gate mask 460.

The second dummy gate electrode layer and the second dummy gate insulation layer may be etched using the second dummy gate mask 460 as an etching mask to form a second dummy gate electrode 450 and a second dummy gate insulation pattern 440, respectively, on the substrate 400.

The second dummy gate insulation pattern 440, the second dummy gate electrode 450 and the second dummy gate mask 460 that are sequentially stacked in the third direction D3 on the second active pattern 405 and a portion of the second isolation pattern 430 adjacent thereto may collectively form a second dummy gate structure 470.

In example embodiments, the second dummy gate structure 470 may extend in the second direction D2 on the fin structure and the second isolation pattern 430, and may cover an upper surface and opposite sidewalls in the second direction D2 of the fin structure.

In example embodiments, a plurality of second dummy gate structures 470 may be spaced apart from each other in the first direction D1.

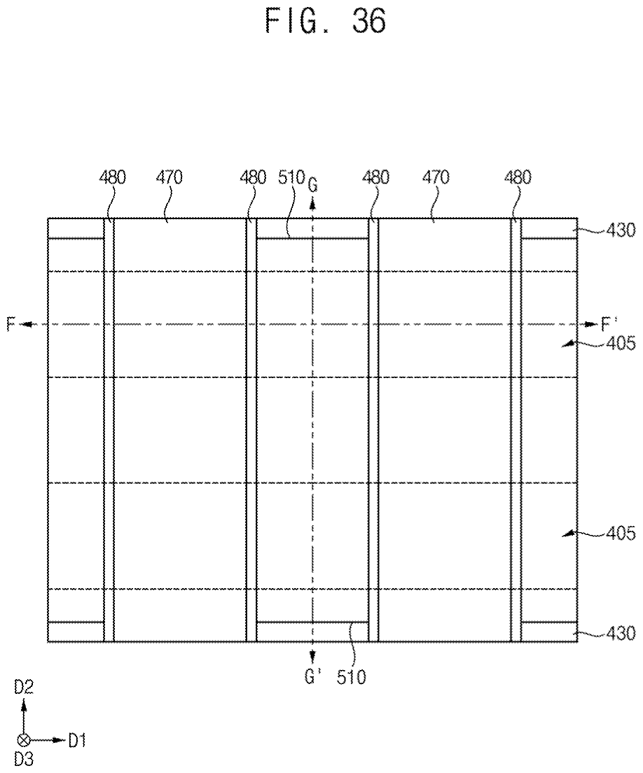

Referring to FIGS. 36 to 38, a second gate spacer 480 may be formed on sidewalls of the second dummy gate structure 470.

For example, a second spacer layer may be formed on the substrate 400 having the fin structure, the second isolation pattern 430 and the second dummy gate structure 470 thereon, and may be anisotropically etched to form the second gate spacer 480 covering each of opposite sidewalls in the first direction D1 of the second dummy gate structure 470.

The fin structure and an upper portion of the second active pattern 405 may be etched using the second dummy gate structure 470 and the second gate spacer 480 as an etching mask to form a fourth opening 490.

Thus, the sacrificial lines 412 and the semiconductor lines 422 under the second dummy gate structure 470 and the second gate spacer 480 may be transformed into sacrificial patterns 414 and semiconductor patterns 424, respectively, and the fin structure extending in the first direction D1 may be divided into a plurality of parts spaced apart from each other in the first direction D1.

Hereinafter, the second dummy gate structure 470, the second gate spacers 480 on opposite sidewalls of the second dummy gate structure 470, and the fin structure may be referred to as a stack structure.

In example embodiments, the stack structure may extend in the second direction D2. In example embodiments, and a plurality of stack structures may be spaced apart from each other in the first direction D1.

In some embodiments, a portion of each of the sacrificial patterns 414 adjacent to the fourth opening 490 may be removed to form a gap, and an inner spacer may be formed in the gap.

A selective epitaxial growth (SEG) process may be performed using the upper surface of the second active pattern 405 and the sidewalls of the semiconductor patterns 424 and the sacrificial patterns 414 exposed by the fourth 490 as a seed to form second source/drain layer 510 in the fourth opening 490.

In an example embodiment, a single crystalline silicon-germanium layer doped with p-type impurities may be formed as the second source/drain layer 510. Alternatively, a single crystalline silicon layer doped with n-type impurities or a single crystalline silicon carbide layer doped with n-type impurities may be formed as each of the second source/drain layer 510.

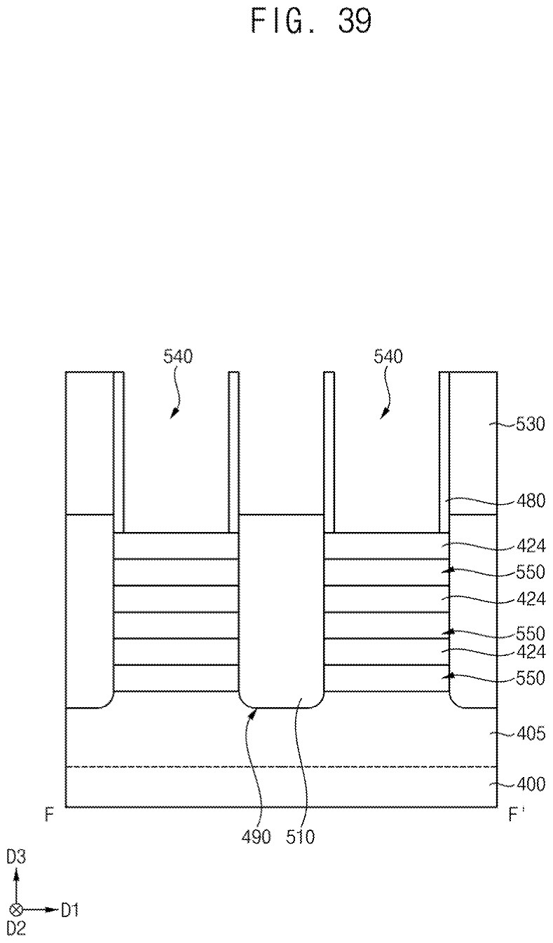

Referring to FIG. 39, a fourth insulating interlayer 530 may be formed on the substrate 400 and may cover the stack structures and the second source/drain layer 510, and a planarization process may be performed until upper surfaces of the second dummy gate electrodes 450 included in the stack structures, respectively, are exposed so that an upper portion of the fourth insulating interlayer 530 and the second dummy gate masks 460 included in the second dummy gate structures 470 may be removed.

The second dummy gate electrodes 450, the second dummy gate insulation patterns 440 and the sacrificial patterns 414 may be removed by, e.g., a wet etching process and/or a dry etching process. Thus, a fifth opening 540 exposing an inner sidewall of the second gate spacer 480 and an upper surface of an uppermost one of the semiconductor patterns 424, and a sixth opening 550 exposing a sidewall of the second source/drain layer 510, surfaces of the semiconductor patterns 424 and an upper surface of the second active pattern 405 may be formed.

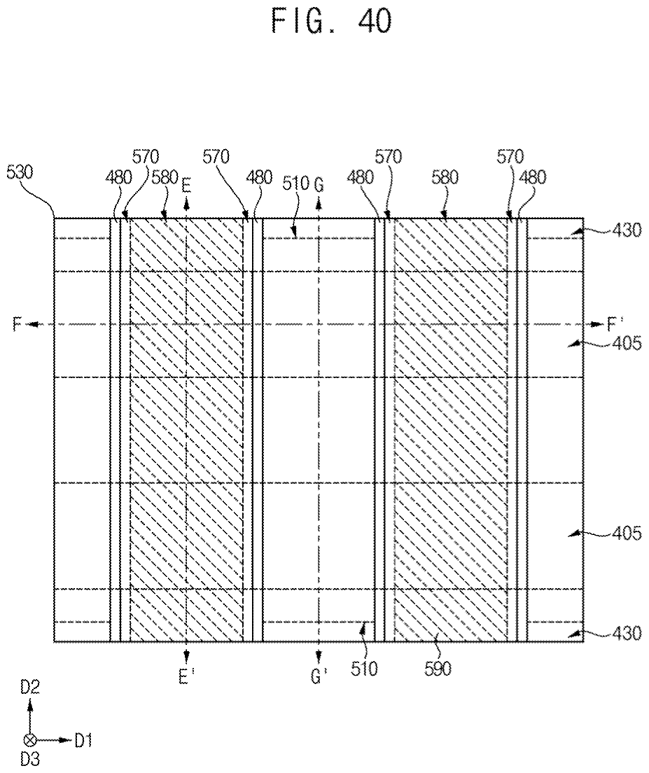

Referring to FIGS. 40 to 42, processes substantially the same as or similar to those illustrated with reference to FIGS. 12 to 14 may be performed.

Thus, a second gate structure 600 including a second gate insulation pattern 570 on the upper surface of the second active pattern 405, the upper surface of the second isolation pattern 430, the sidewall of the second source/drain layer 510, the surfaces of the semiconductor patterns 424 and an inner lower sidewall of the second gate spacer 480 in the fifth and sixth openings 540 and 550, and a second gate electrode 580 on the second gate insulation pattern 570 and filling a lower portion of the fifth opening 540 and the sixth opening 550, and a second capping pattern 590 on the second gate structure 600 and filling an upper portion of the fifth opening 540 to contact an inner upper sidewall of the second gate spacer 480 may be formed.

In an example embodiment, an interface pattern including, e.g., silicon oxide may be further formed on the upper surface of the second active pattern 405 and the surfaces of the semiconductor patterns 424.

Referring to FIGS. 27 to 30 again, processes substantially the same as or similar to those illustrated with reference to FIGS. 15 to 23 and FIGS. 1 to 4 may be performed.

Thus, a fifth insulating interlayer 620 may be formed on the second gate structure 600, the second gate spacer 480 and the fourth insulating interlayer 530, and a third contact plug 625 may be formed through the fourth and fifth insulating interlayers 530 and 620 to contact an upper surface of the second source/drain layer 510. Additionally, a fourth contact plug 670 may be formed through the second capping pattern 590 and the fourth and fifth insulating interlayers 620 and 630 to contact an upper surface of the second gate electrode 580 of the second gate structure 600. The fourth contact plug 670 may include the third and fourth conductive patterns 655 and 665 that are sequentially stacked in the third direction D3.

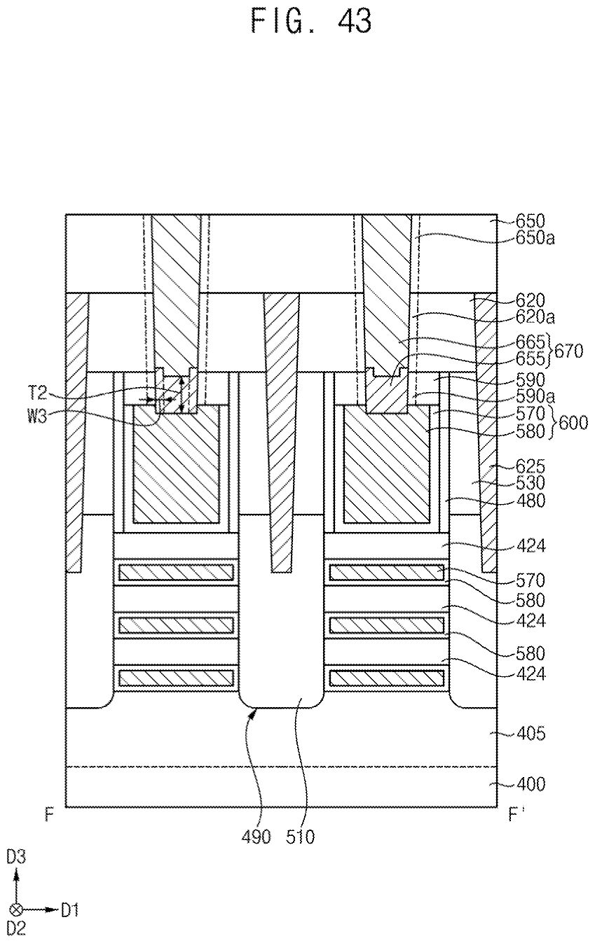

FIGS. 43 to 45 are cross-sectional views illustrating semiconductor devices in accordance with example embodiments, which may correspond to FIG. 29.

These semiconductor devices may include the characteristics of the semiconductor devices shown in FIGS. 24 to 26, and thus to the extent that an element is not described in detail, it may be assumed that the element is at least similar to a corresponding element that has been described elsewhere within the present disclosure.

Referring to FIG. 43, an upper surface of an edge portion of the third conductive pattern 655 may be higher than an upper surface a central portion of the third conductive pattern 655. Accordingly, a lower surface of a central portion of the fourth conductive pattern 665 may be lower than a lower surface of an edge portion of the third conductive pattern 655.

A third width W3 of the edge portion of the third conductive pattern 655 may be substantially constant at a height that is higher than the upper surface of the central portion of the third conductive pattern 655.

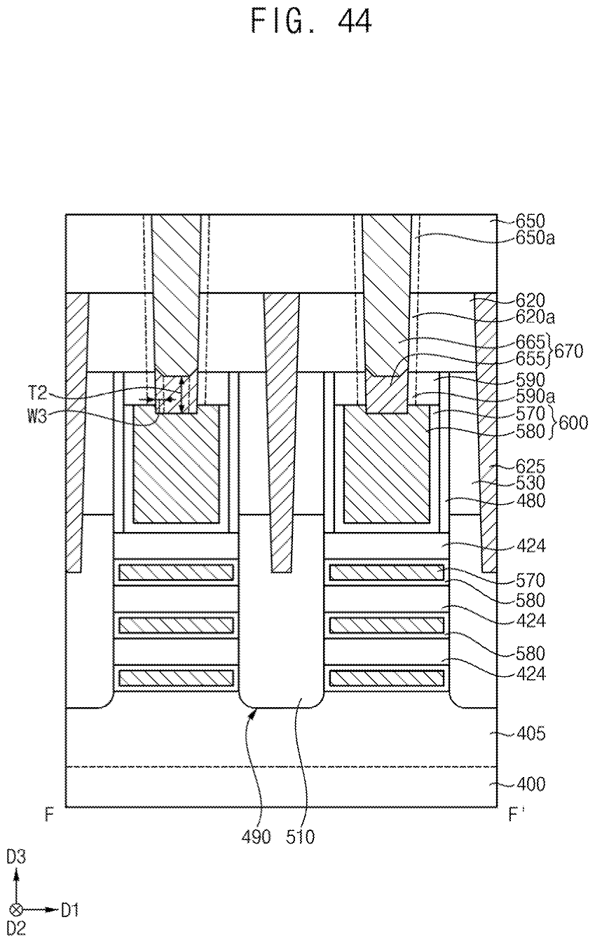

Referring to FIG. 44, the upper surface of the edge portion of the third conductive pattern 655 may be higher than the upper surface of the central portion of third conductive pattern 655. Accordingly, the lower surface of the central portion of the fourth conductive pattern 665 may be lower than the lower surface of the edge portions of the third conductive pattern 655.

The third width W3 of the edge portion of the third conductive pattern 655 may decrease from a bottom to top thereof in the third direction D3 at the height that is higher than the upper surface of the central portion of the third conductive pattern 655. Accordingly, a sidewall of the edge portion of the third conductive pattern 655 may be inclined with respect to the upper surface of the substrate 400 at the height that is higher than the upper surface of the central portion of the third conductive pattern 655.

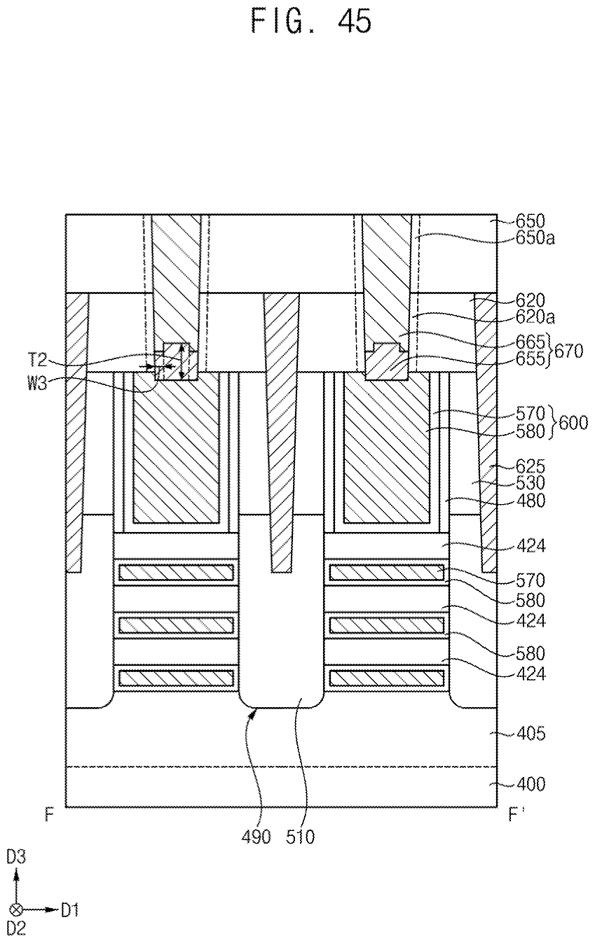

Referring to FIG. 45, the second capping pattern 590 might not be formed on the second gate structure 600, and thus the fourth contact plug 670 may extend through the fifth and sixth insulating interlayers 620 and 650 to contact the upper surface of the second gate structure 600.

The foregoing is illustrative of example embodiments and is not necessarily to be construed as limiting thereof. Although a few example embodiments have been described, those skilled in the art will readily appreciate that many modifications are possible in the example embodiments without materially departing from the novel teachings and aspects of the present inventive concept. Accordingly, all such modifications are intended to be included within the scope of the present inventive concept.

What is claimed is:

1. A semiconductor device, comprising:
a gate structure disposed on a substrate; and
a contact plug including:
a first conductive pattern contacting an upper surface of the first gate structure; and
a second conductive pattern contacting an upper surface of the first conductive pattern,
wherein an upper surface of a central portion of the first conductive pattern is higher than an upper surface of an edge portion of the first conductive pattern, and
wherein a lower surface of a central portion of the second conductive pattern is higher than a lower surface of an edge portion of the second conductive pattern.

2. The semiconductor device as claimed in claim 1, wherein a width of the edge portion of the first conductive pattern, in a horizontal direction substantially parallel to an upper surface of the substrate, is smaller than a thickness of the central portion of the first conductive pattern, in a vertical direction substantially perpendicular to the upper surface of the substrate.

3. The semiconductor device as claimed in claim 1, wherein the first and second conductive patterns include a same metal.

4. The semiconductor device as claimed in claim 3, wherein the second conductive pattern further includes fluorine, chlorine, boron and/or silicon.

5. The semiconductor device as claimed in claim 3, further comprising an insulating interlayer disposed on the gate structure, the insulating interlayer covering a sidewall of the contact plug,
wherein a portion of the insulating interlayer adjacent to the contact plug further includes the metal of the first and second conductive patterns.

6. The semiconductor device as claimed in claim 1, wherein the gate structure includes:
a gate electrode; and
a gate insulation pattern disposed on a lower surface and a sidewall of the gate electrode,
wherein the first conductive pattern directly contacts the gate electrode.

7. The semiconductor device as claimed in claim 1, further comprising a plurality of channels spaced apart from each other in a vertical direction substantially perpendicular to an upper surface of the substrate, each of the channels extending through the gate structure.

8. A semiconductor device, comprising:
a gate structure disposed on a substrate; and
a contact plug including:
a first conductive pattern contacting an upper surface of the first gate structure; and
a second conductive pattern contacting an upper surface of the first conductive pattern,
wherein an upper surface of an edge portion of the first conductive pattern is higher than an upper surface of a central portion of the first conductive pattern,
wherein a lower surface of a central portion of the second conductive pattern is lower than a lower surface of an edge portion of the second conductive pattern,
wherein a width of the edge portion of the first conductive pattern, in a horizontal direction substantially parallel to an upper surface of the substrate, is smaller than a thickness of the substrate of the central portion of the first conductive pattern, in a vertical direction substantially perpendicular to the upper surface.

9. The semiconductor device as claimed in claim 8, wherein the width of the edge portion of the first conductive pattern is substantially constant along the vertical direction.

10. The semiconductor device as claimed in claim 8, wherein the width of the edge portion of the first conductive pattern decreases in the vertical direction from a portion of the edge portion of the first conductive pattern at a height of the upper surface of the central portion of the first conductive pattern to an uppermost portion of the edge portion of the first conductive pattern.

11. The semiconductor device as claimed in claim 8, wherein the first and second conductive patterns include a same metal.

12. The semiconductor device as claimed in claim 11, wherein the second conductive pattern further includes fluorine, chlorine, boron and/or silicon.

13. The semiconductor device as claimed in claim 11, further comprising an insulating interlayer disposed on the gate structure, the insulating interlayer covering a sidewall of the contact plug,
wherein a portion of the insulating interlayer adjacent to the contact plug further includes the metal of the first and second conductive patterns.

14. The semiconductor device as claimed in claim 13, wherein the second conductive pattern directly contacts the insulating interlayer.

15. A semiconductor device, comprising:
an active pattern disposed on a substrate, the active pattern extending in a first direction that is substantially parallel to an upper surface of the substrate,
a gate structure disposed on the active pattern, the gate structure extending in a second direction that is substantially parallel to the upper surface of the substrate and crosses the first direction;
a source/drain layer disposed on the active pattern adjacent to the gate structure in the first direction;
a plurality of channels spaced apart from each other in a third direction that is substantially perpendicular to the upper surface of the substrate;
an insulating interlayer disposed on the gate structure; and
a contact plug extending through the insulating interlayer and contacting an upper surface of the gate structure, the contact plug including:
a first conductive pattern including a first metal; and
a second conductive pattern contacting an upper surface of the first conductive pattern and including a second metal,
wherein an upper surface of a central portion of the first conductive pattern being higher than an upper surface of an edge portion of the first conductive pattern, and
wherein a lower surface of a central portion of the second conductive pattern being higher than a lower surface of an edge portion of the second conductive pattern.

16. The semiconductor device as claimed in claim 15, wherein the second conductive pattern directly contacts the insulating interlayer.

17. The semiconductor device as claimed in claim 15, wherein a portion of the insulating interlayer adjacent to the contact plug further includes the first metal.

18. The semiconductor device as claimed in claim 16, wherein the second conductive pattern further includes fluorine, chlorine, boron and/or silicon.

19. The semiconductor device as claimed in claim 15, wherein a width of the edge portion of the first conductive pattern, in a horizontal direction substantially parallel to the upper surface of the substrate, is smaller than a thickness of the central portion of the first conductive pattern in the third direction.

20. The semiconductor device as claimed in claim 15, wherein the gate structure includes:
a gate electrode; and
a gate insulation pattern disposed on a lower surface and a sidewall of the gate electrode,
wherein the first conductive pattern directly contacts the gate electrode.
